(19) United States
(12) Patent Application Publication
(10) Pub. No.: US 2023/0197856 A1
(43) Pub. Date: Jun. 22, 2023

(54) SEMICONDUCTOR DEVICE STRUCTURE AND METHOD FOR FORMING THE SAME

(71) Applicant: TAIWAN SEMICONDUCTOR MANUFACTURING COMPANY, LTD., Hsinchu (TW)

(72) Inventors: Shih-Cheng CHEN, New Taipei City (TW); Zhi-Chang LIN, Zhubei City (TW); Jung-Hung CHANG, Changhua County (TW); Chien-Ning YAO, Hsinchu (TW); Tsung-Han CHUANG, Tainan City (TW); Kuo-Cheng CHIANG, Zhubei City (TW); Chih-Hao WANG, Baoshan Township (TW)

(73) Assignee: TAIWAN SEMICONDUCTOR MANUFACTURING COMPANY, LTD., Hsinchu (TW)

(21) Appl. No.: 17/685,584

(22) Filed: Mar. 3, 2022

Related U.S. Application Data
(60) Provisional application No. 63/255,134, filed on Oct. 13, 2021.

(51) Int. Cl. H01L 29/786; H01L 27/092; H01L 29/06; H01L 29/423; H01L 21/02; H01L 21/8238; H01L 29/66

(52) U.S. Cl. CPC H01L 29/78618; H01L 21/0259; H01L 21/823807; H01L 21/823814; H01L 27/092; H01L 29/0665; H01L 29/42392; H01L 29/66545; H01L 29/66553; H01L 29/66742; H01L 29/78696

(57) ABSTRACT

A semiconductor device structure and method for forming the same are provided. The semiconductor device structure includes a plurality of first nanostructures stacked over a substrate in a vertical direction. The semiconductor device structure also includes a first bottom layer formed adjacent to the first nanostructures, and a first dielectric layer formed over the first bottom layer. The semiconductor device structure further includes a first source/drain (S/D) structure formed over the first dielectric layer, and the first S/D structure is isolated from the first bottom layer by the first dielectric layer.

### CROSS REFERENCE TO RELATED APPLICATIONS

This Application claims the benefit of U.S. Provisional Application No. 63/255,134 filed on Oct. 13, 2021, the entirety of which is incorporated by reference herein.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon. Many integrated circuits are typically manufactured on a single semiconductor wafer, and individual dies on the wafer are singulated by sawing between the integrated circuits along a scribe line. The individual dies are typically packaged separately, in multi-chip modules, for example, or in other types of packaging.

As the semiconductor industry has progressed into nanometer technology process nodes in pursuit of higher device density, higher performance, and lower costs, challenges from both fabrication and design issues have resulted in the development of three-dimensional designs.

Although existing semiconductor devices have generally been adequate for their intended purposes, they have not been entirely satisfactory in all respects.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1H show perspective representations of various stages of forming a semiconductor device structure, in accordance with some embodiments of the disclosure.

FIGS. 1F-1, 1G-1, 1H-1 show cross-sectional representations of the semiconductor device structure along line X-X’ shown in FIGS. 1F-1H, in accordance with some embodiments of the disclosure.

FIGS. 1F-2, 1G-2, 1H-2 show cross-sectional representations of the semiconductor device structure along line Y-Y’ shown in FIGS. 1F-1H, in accordance with some embodiments of the disclosure.

FIGS. 2A-2J show cross-sectional representations of various stages of forming a semiconductor device structure and a semiconductor device structure, in accordance with some embodiments of the disclosure.

FIG. 2E’ show cross-sectional representation of a semiconductor device structure and a semiconductor device structure, in accordance with some embodiments of the disclosure.

FIG. 2F’ show cross-sectional representation of a semiconductor device structure and a semiconductor device structure, in accordance with some embodiments of the disclosure.

FIG. 2F” show cross-sectional representation of a semiconductor device structure and a semiconductor device structure, in accordance with some embodiments of the disclosure.

FIG. 2J’ show cross-sectional representation of a semiconductor device structure and a semiconductor device structure, in accordance with some embodiments of the disclosure.

FIG. 2J” show cross-sectional representation of a semiconductor device structure and a semiconductor device structure, in accordance with some embodiments of the disclosure.

FIG. 3 shows a cross-sectional representation of the semiconductor device structure and the semiconductor device structure along Y-Y’ direction, in accordance with some embodiments of the disclosure.

FIGS. 4A-4C show top-views of the layout of the first region and the second region, in accordance with some embodiments of the disclosure.

FIG. 5A shows a cross-sectional representation of the semiconductor device structure along the Y-Y’ direction, in accordance with some embodiments.

FIG. 5B shows a cross-sectional representation of the semiconductor device structure along the X-X’ direction, in accordance with some embodiments.

FIG. 6A shows a cross-sectional representation of the semiconductor device structure along the Y-Y’ direction, in accordance with some embodiments.

FIG. 6B shows a cross-sectional representation of the semiconductor device structure along the X-X′ direction, in accordance with some embodiments.

FIG. 7 shows a cross-sectional representation of the semiconductor device structure along the Y-Y’ direction in a cell, in accordance with some embodiments.

FIG. 8 shows a cross-sectional representation of the semiconductor device structure along the Y-Y’ direction in a cell, in accordance with some embodiments.

FIG. 9 shows a cross-sectional representation of the semiconductor device structure along the Y-Y’ direction in a cell, in accordance with some embodiments.

FIG. 10 shows a cross-sectional representation of the semiconductor device structure along the Y-Y’ direction in a cell, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numbers are used to designate like elements. It should be understood that additional operations can be provided before, during, and after the method, and some of the operations described can be replaced or eliminated for other embodiments of the method.

The nanostructure transistor (e.g. nanosheet transistor, nanowire transistor, multi-bridge channel, nano-ribbon FET, gate all around (GAA) transistor structures) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

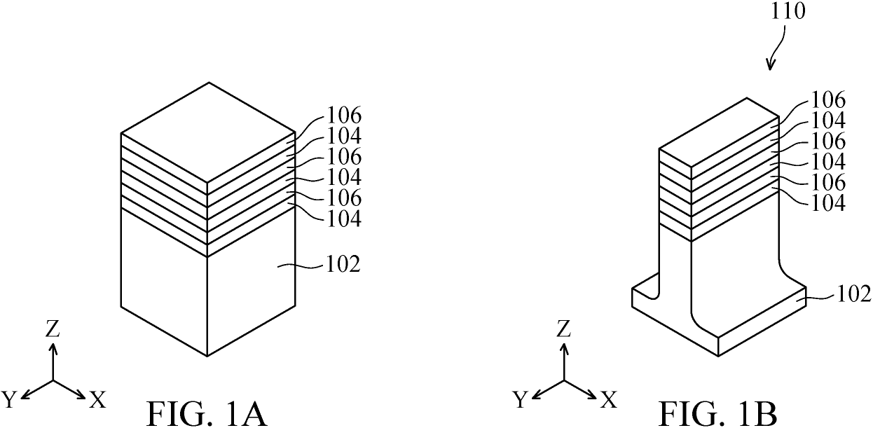

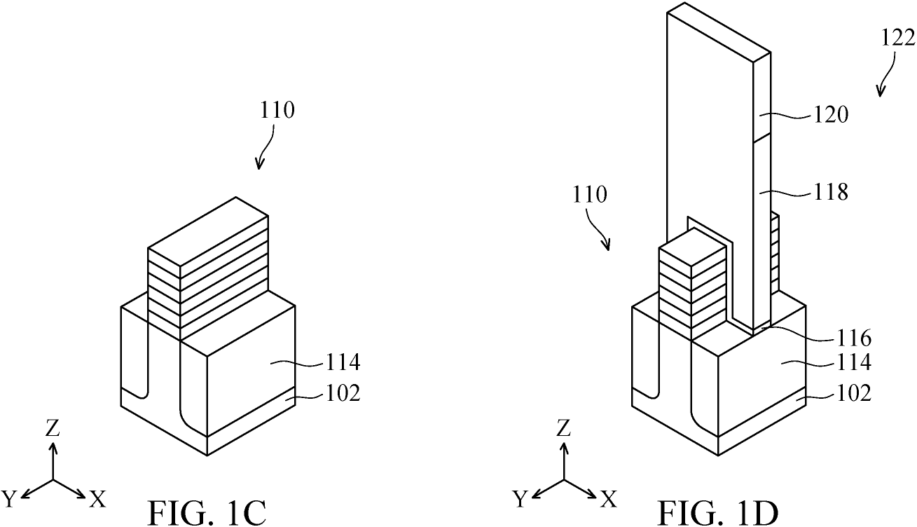

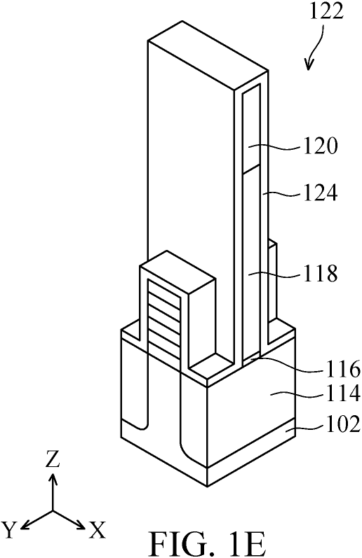

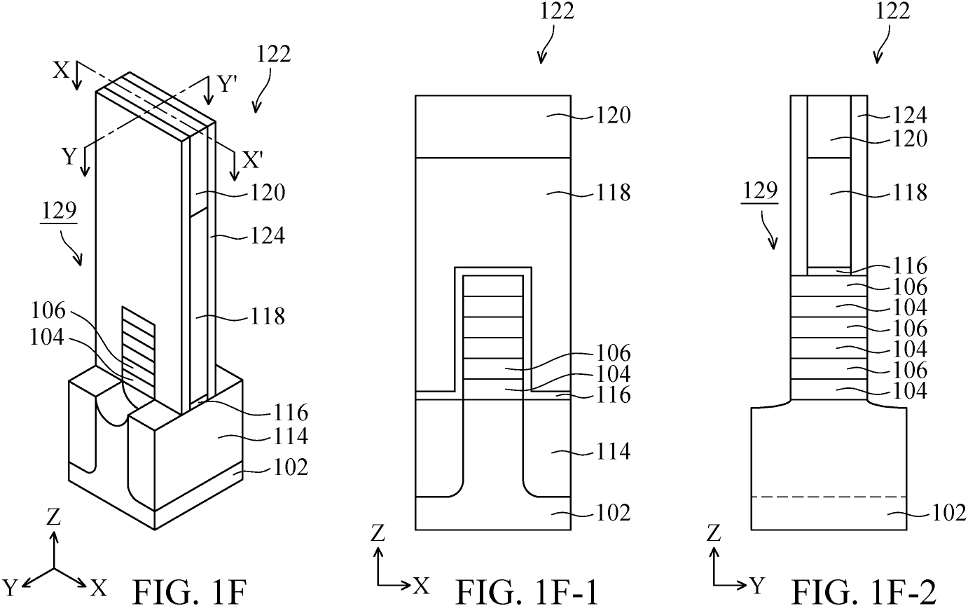

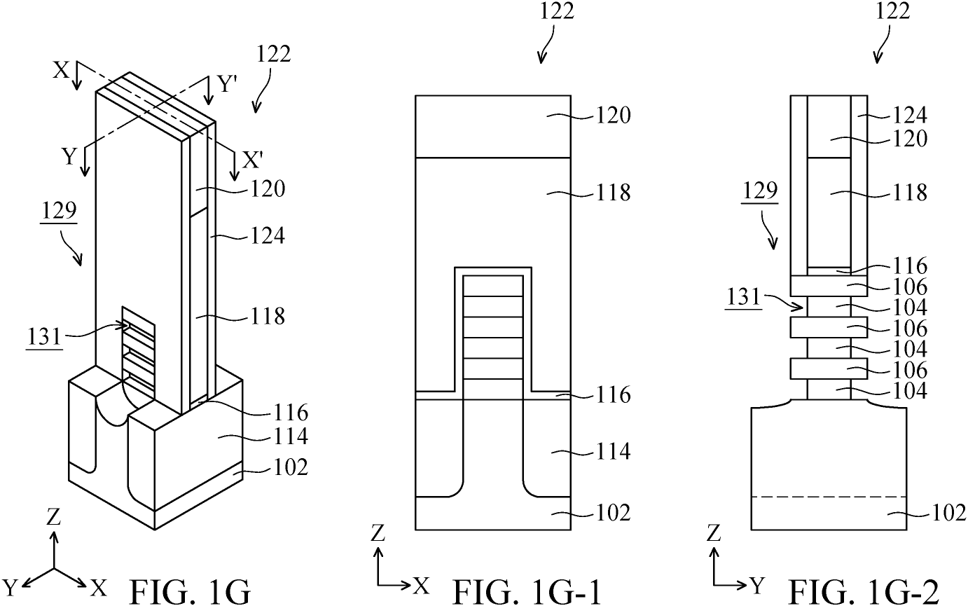

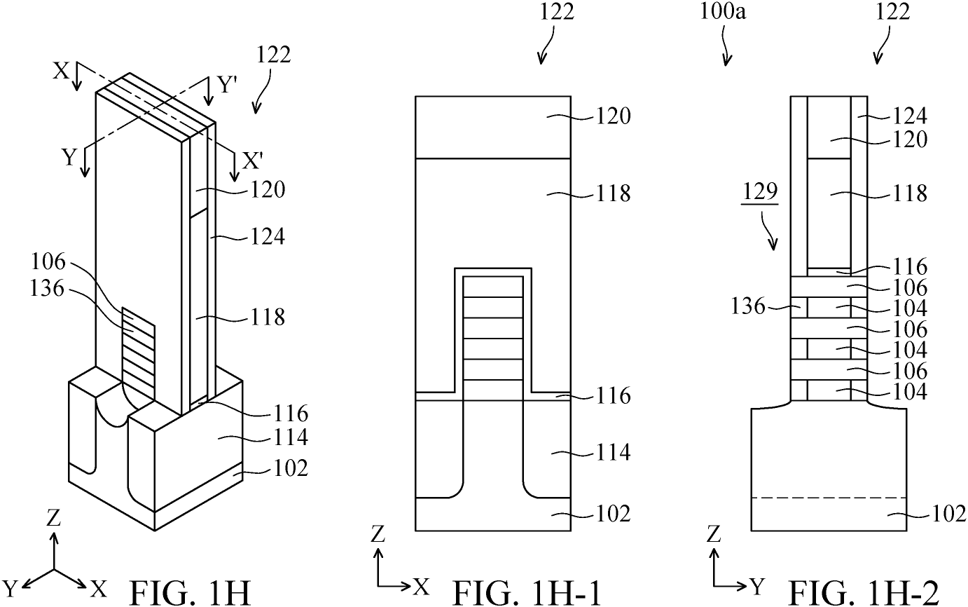

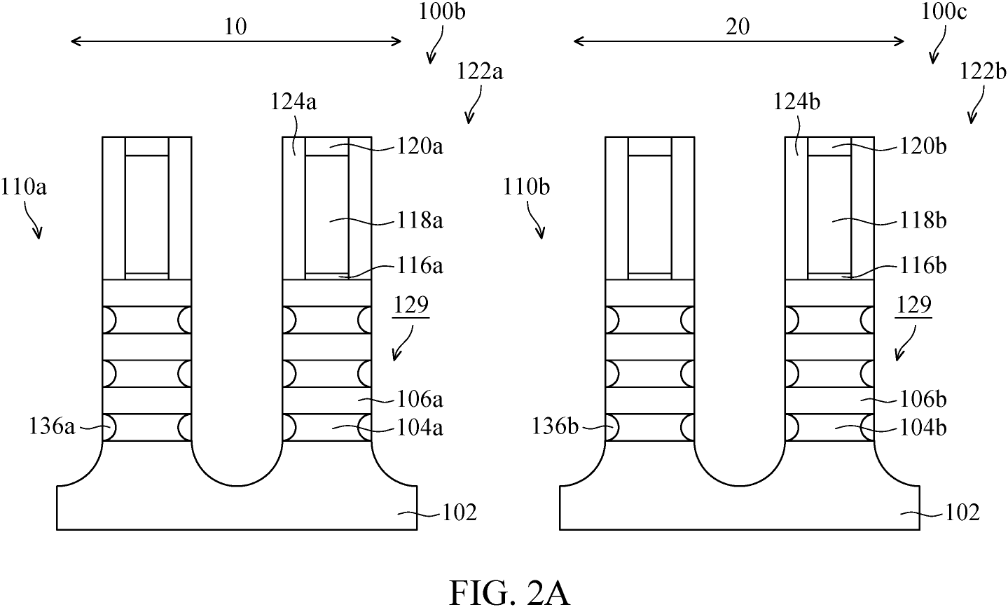

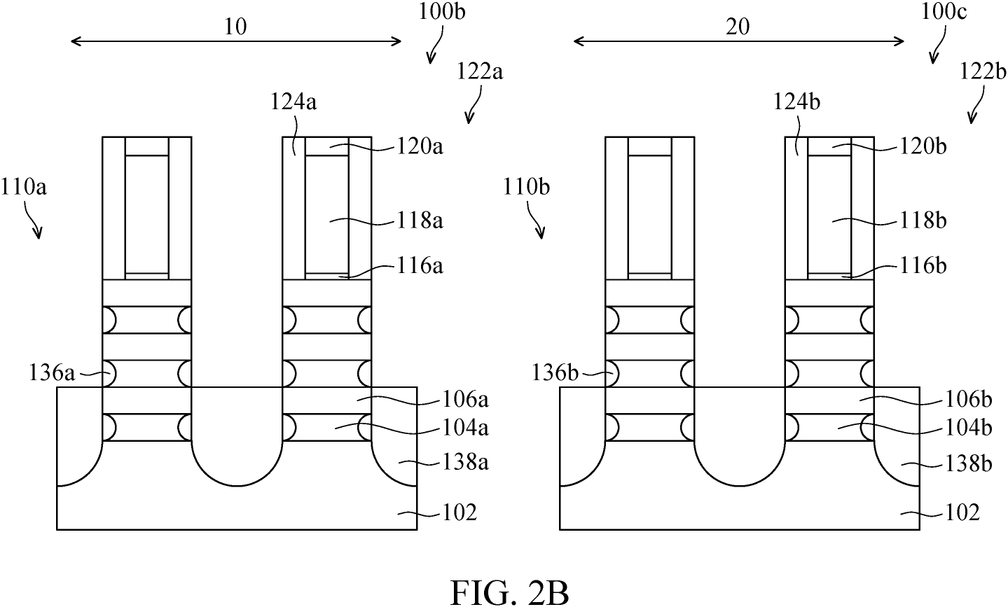

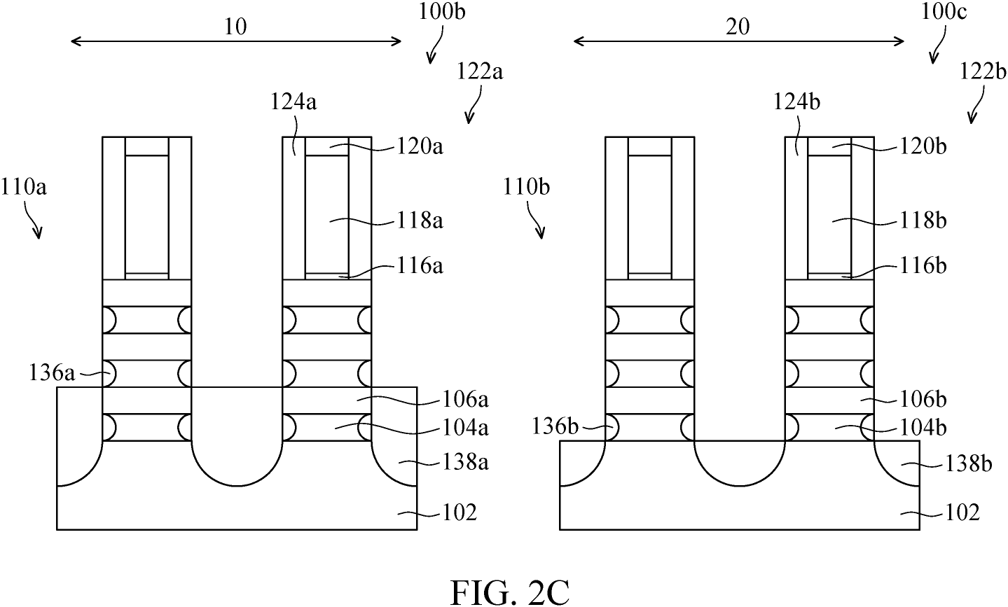

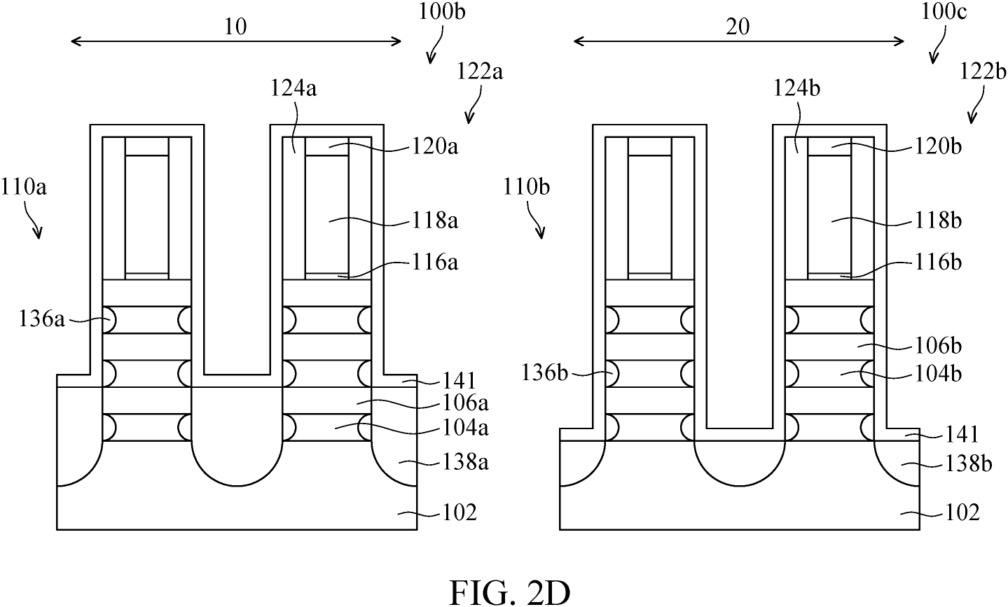

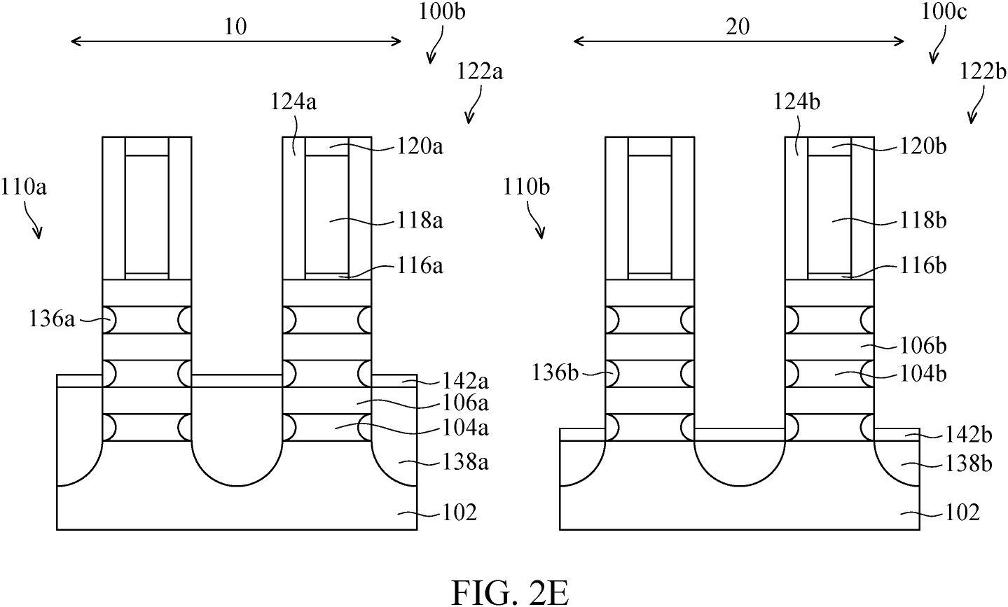

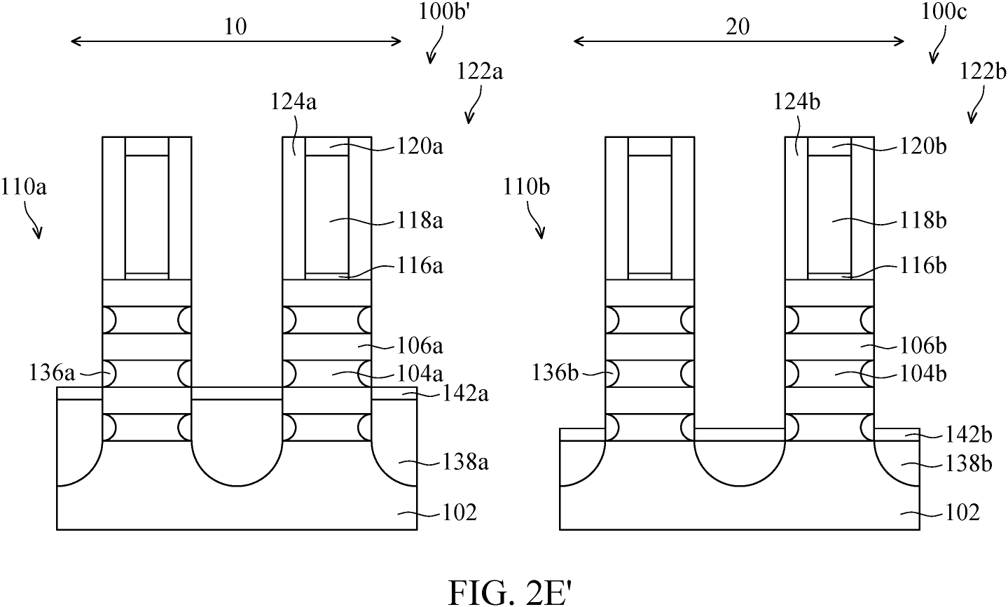

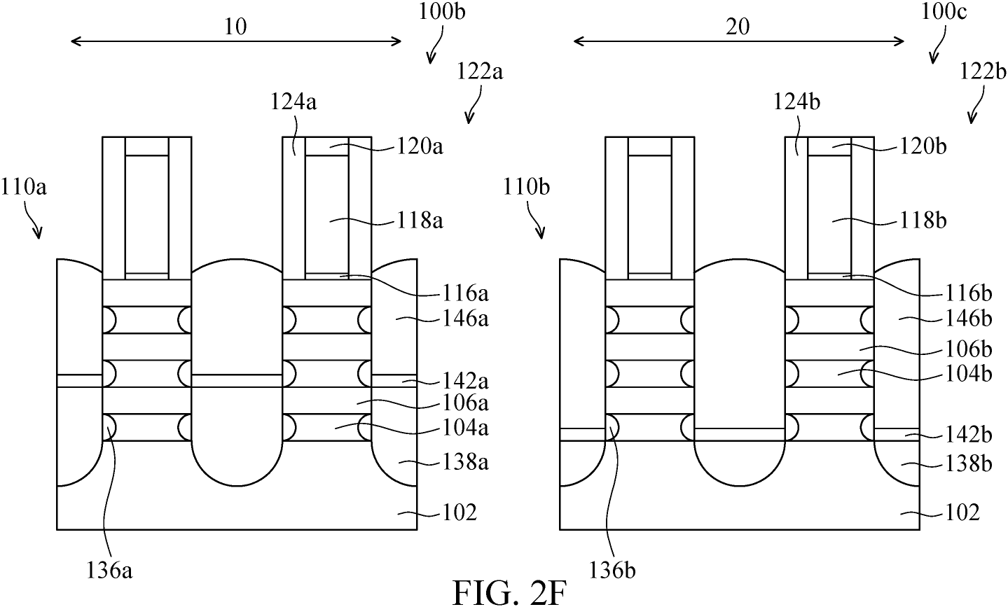

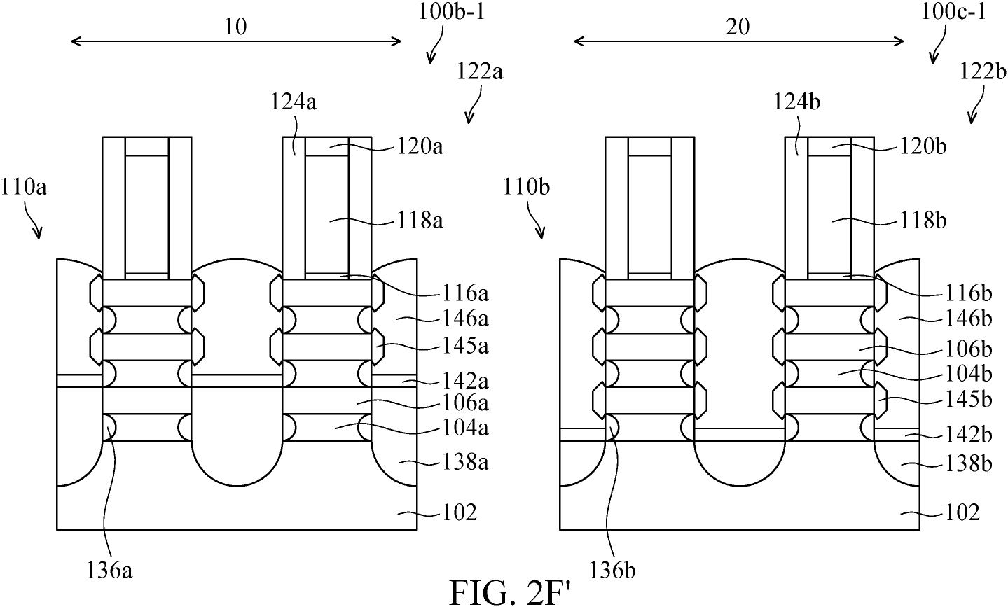

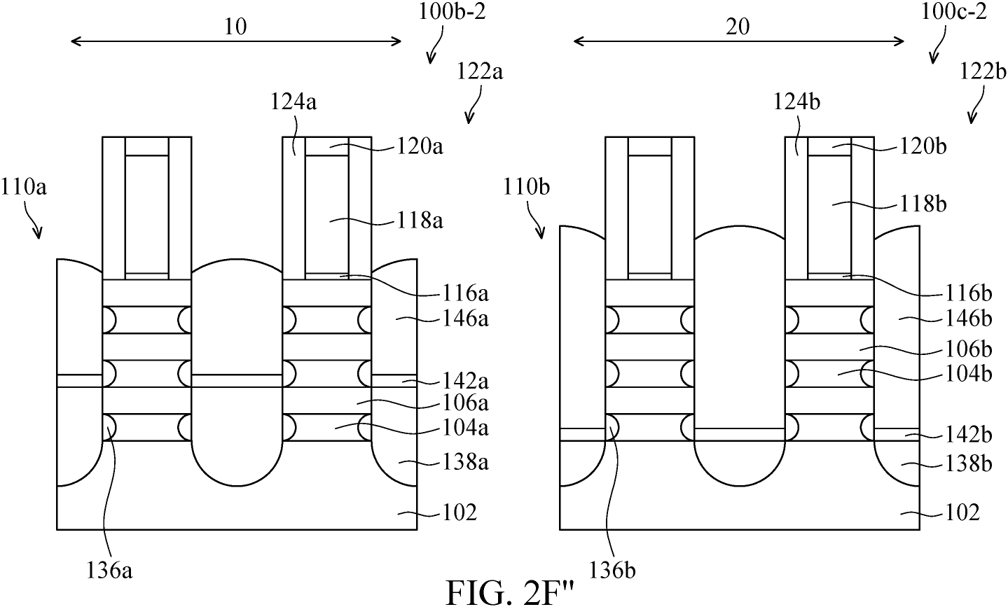

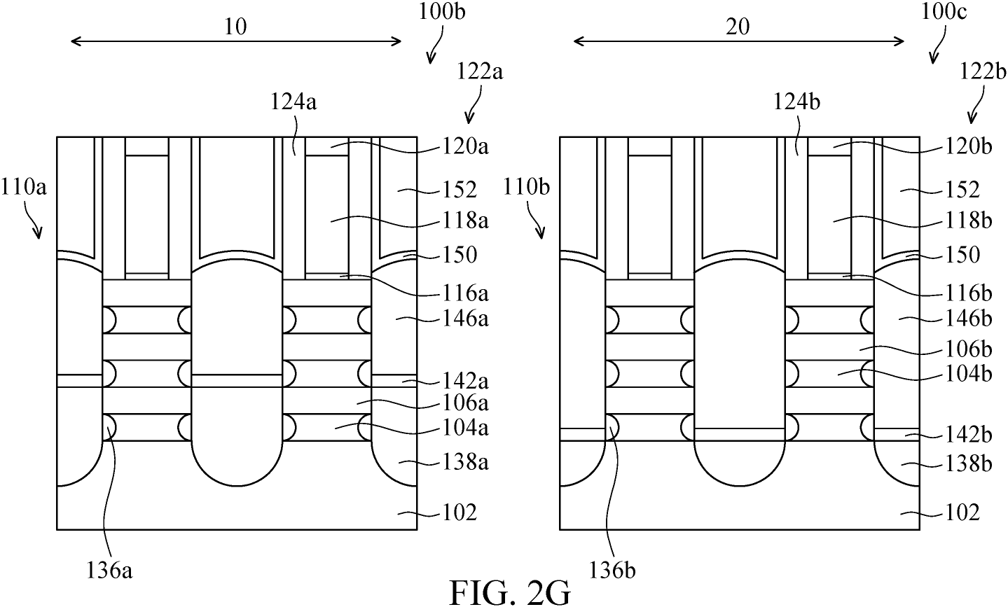

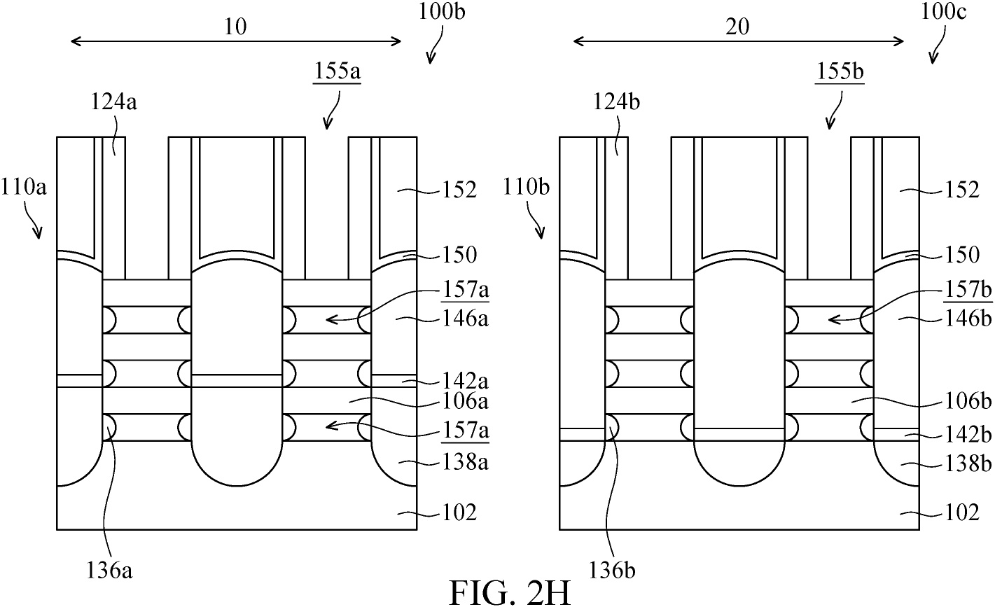

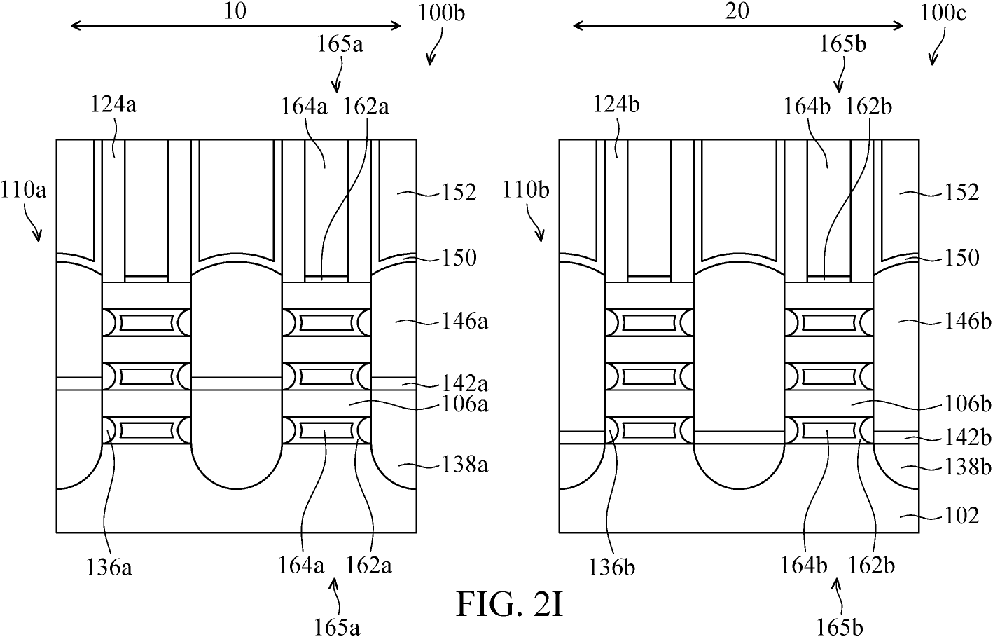

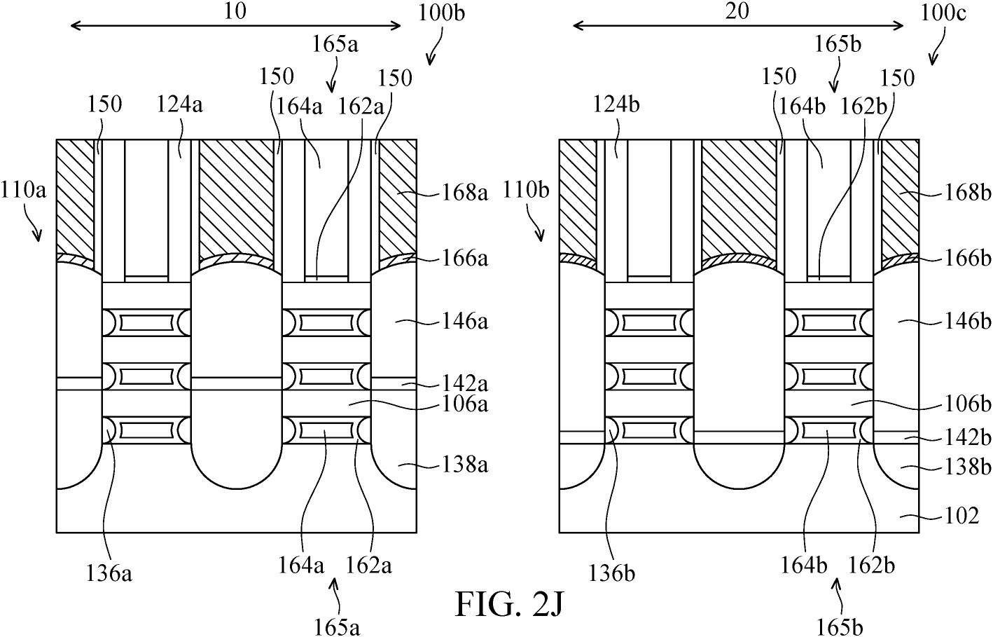

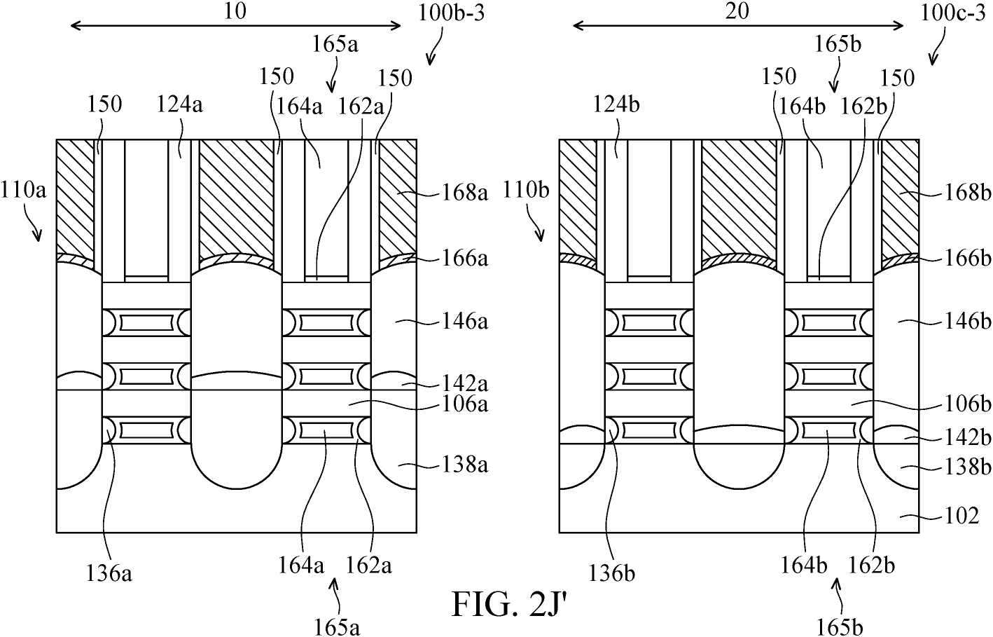

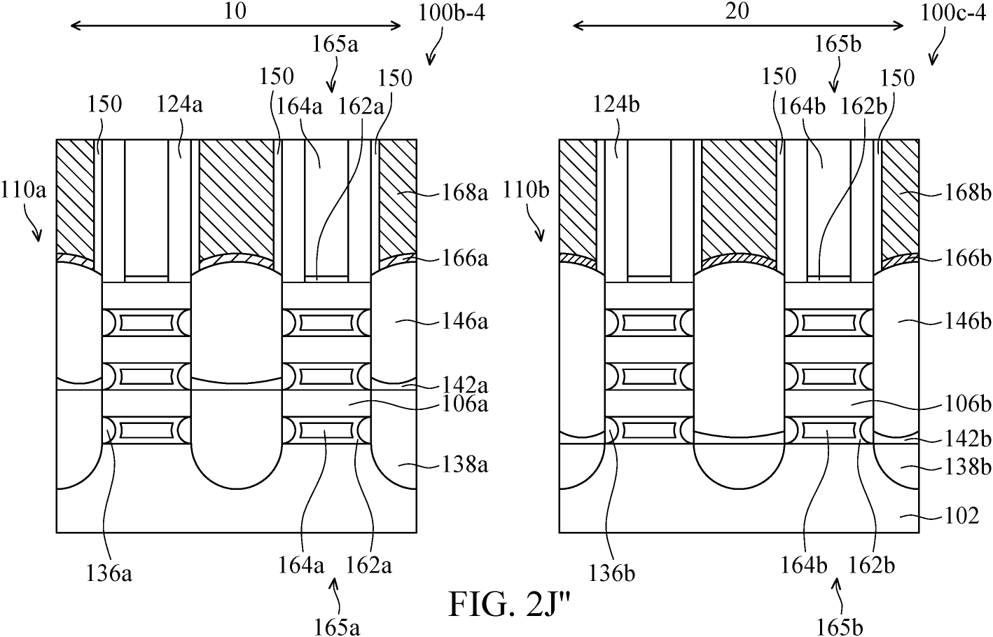

Embodiments for forming a semiconductor device structure are provided. FIGS. 1A-1H show perspective representations of various stages of forming a semiconductor device structure 100a, in accordance with some embodiments of the disclosure. FIGS. 1F-1, 1G-1, 1H-1 show cross-sectional representations of the semiconductor device structure along line X-X’ shown in FIGS. 1F-1H, in accordance with some embodiments of the disclosure. FIGS. 1F-2, 1G-2, 1H-2 show cross-sectional representations of the semiconductor device structure along line Y-Y’ shown in FIGS. 1F-1H, in accordance with some embodiments of the disclosure. The semiconductor device structure 100a is a gate all around (GAA) transistor structure.

As shown in FIG. 1A, a substrate 102 is provided. The substrate 102 may be made of silicon or other semiconductor materials. Alternatively or additionally, the substrate 102 may include other elementary semiconductor materials such as germanium. In some embodiments, the substrate 102 is made of a compound semiconductor such as silicon carbide, gallium arsenic, indium arsenide, or indium phosphide. In some embodiments, the substrate 102 is made of an alloy semiconductor such as silicon germanium, silicon germanium carbide, gallium arsenic phosphide, or gallium indium phosphide. In some embodiments, the substrate 102 includes an epitaxial layer. For example, the substrate 102 has an epitaxial layer overlying a bulk semiconductor.

A number of first semiconductor layers 104 and a number of second semiconductor layers 106 are sequentially alternately formed over the substrate 102. The semiconductor layers 104 and 106 are vertically stacked to form a stacked nanostructures structure (or a stacked nanosheet or a stacked nanowire).

In some embodiments, the first semiconductor layers 104 and the second semiconductor layers 106 independently include silicon (Si), germanium (Ge), silicon germanium (Si₁₋ₓGex, 0.1 <x<0.7, the value x is the atomic percentage of germanium (Ge) in the silicon germanium), indium arsenide (InAs), indium gallium arsenide (InGaAs), indium antimonide (InSb), or another applicable material. In some embodiments, the first semiconductor layer 104 and the second semiconductor layer 106 are made of different materials.

The first semiconductor layers 104 and the second semiconductor layers 106 are made of different materials having different lattice constant. In some embodiments, the first semiconductor layer 104 is made of silicon germanium (Si₁₋ₓGex, 0.1 <x<0.7), and the second semiconductor layer 106 is made of silicon (Si). In some other embodiments, the first semiconductor layer 104 is made of silicon (Si), and the second semiconductor layer 106 is made of silicon germanium (Si₁₋ₓGex, 0.1 <x<0.7).

In some embodiments, the first semiconductor layers 104 and the second semiconductor layers 106 are formed by a selective epitaxial growth (SEG) process, a chemical vapor deposition (CVD) process (e.g. low-pressure CVD (LPCVD), plasma enhanced CVD (PECVD)), a molecular epitaxy process, or another applicable process. In some embodiments, the first semiconductor layers 104 and the second semiconductor layers 106 are formed in-situ in the same chamber.

In some embodiments, the thickness of each of the first semiconductor layers 104 is in a range from about 1.5 nanometers (nm) to about 20 nm. Terms such as “about” in conjunction with a specific distance or size are to be interpreted as not to exclude insignificant deviation from the specified distance or size and may include for example deviations of up to 20%. In some embodiments, the first semiconductor layers 104 are substantially uniform in thickness. In some embodiments, the thickness of each of the second semiconductor layers 106 is in a range from about 1.5 nm to about 20 nm. In some embodiments, the second semiconductor layers 106 are substantially uniform in thickness.

Then, as shown in FIG. 1B, the first semiconductor layers 104 and the second semiconductor layers 106 are patterned to form a fin structure 110, in accordance with some embodiments of the disclosure. In some embodiments, a liner layer (not shown) is formed on sidewall surfaces of the fin structure 110.

Afterwards, as shown in FIG. 1C, an isolation structure 114 is formed over the substrate 102, in accordance with some embodiments of the disclosure. The top portions of the fin structures 110 are above the isolation structure 114.

Next, as shown in FIG. 1D, a dummy gate dielectric layer 116 and a dummy gate electrode layer 118 are formed over the fin structure 110, and then a hard mask layer 120 is formed on the dummy gate electrode layer 118. Afterwards, the dummy gate dielectric layer 116, the dummy gate electrode layer 118 and the hard mask layer 120 are patterned by a patterning process. As a result, a dummy gate structure 122 is constructed by the dummy gate dielectric layer 116, the dummy gate electrode layer 118 and the hard mask layer 120.

The patterning process includes a photolithography process and an etching process. The photolithography process includes photoresist coating (e.g., spin-on coating), soft baking, mask aligning, exposure, post-exposure baking, developing the photoresist, rinsing and drying (e.g., hard baking). The etching process includes a dry etching process or a wet etching process.

The dummy gate electrode layer 118 is formed to partially cover and to extend across the fin structure 110. In some embodiments, the dummy gate electrode layer 118 wraps around the fin structure 110. The dummy gate dielectric layers 116 may be made of or include silicon oxide. In some embodiments, the dummy gate electrode layer 118 is made of polycrystalline-silicon (poly-Si) or poly-crystalline silicon-germanium (poly-SiGe).

Afterwards, as shown in FIG. 1E, a gate spacer layer 124 is formed on opposite sidewall surfaces of the dummy gate structure 122, in accordance with some embodiments. The gate spacer layer 124 can provide more protection to the dummy gate structure 122 during subsequent processes.

In some embodiments, the gate spacer layer 124 is made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. In some embodiments, the gate spacer layer 124 is formed by a deposition process, such as CVD process, ALD process, another applicable process, or a combination thereof.

Next, as shown in FIG. 1F, a portion of the fin structure 110 is removed to form an S/D trench 129, in accordance with some embodiments. FIG. 1F-1 shows a cross-sectional representation of the semiconductor device structure along line X-X’ shown in FIG. 1F, in accordance with some embodiments of the disclosure. FIG. 1F-2 shows a cross-sectional representations of the semiconductor device structure along line Y-Y’ shown in FIG. 1F, in accordance with some embodiments of the disclosure.

More specifically, as shown in FIGS. 1F, 1F-1 and 1F-2, a portion of the first semiconductor layers 104 and a portion of the second semiconductor layers 106 which are not covered by the dummy gate structure 122 are removed to form the S/D trench 129.

Afterwards, as shown in FIG. 1G, a portion of the first semiconductor layers 104 is removed to form a number of cavities 131, in accordance with some embodiments. FIG. 1G-1 shows a cross-sectional representation of the semiconductor device structure along line X-X’ shown in FIG. 1G, in accordance with some embodiments of the disclosure. FIG. 1G-2 shows a cross-sectional representation of the semiconductor device structure along line Y-Y” shown in FIG. 1G, in accordance with some embodiments of the disclosure.

As shown in FIGS. 1G, 1G-1 and 1G-2, each of the cavities 131 is between two adjacent second semiconductor layers 106. The cavities 131 are exposed by the S/D trench 129. The portion of the first semiconductor layers 104 is removed by using an etching process, such as a dry etching process or a wet etching process. In some embodiments, the first semiconductor layers 104 are made of SiGe and are removed by a wet etching process, and the wet etching process includes using HF and F₂.

The cavities 131 are used to provide a space for forming the number of the inner spacer layers 136 (formed later). The cavities 131 are directly below the gate spacer layer 124. In some embodiments, after the cavities 131 are formed, a clean process is performed on the cavities. In some embodiments, the cleaning process includes using DI water.

Next, as shown in FIG. 1H, the inner spacer layers 136 are formed in the cavity 131 and on the gate spacer layer 124, in accordance with some embodiments. FIG. 1H-1 shows a cross-sectional representation of the semiconductor device structure along line X-X’ shown in FIG. 1H, in accordance with some embodiments of the disclosure. FIG. 1H-2 shows a cross-sectional representation of the semiconductor device structure along line Y-Y” shown in FIG. 1H, in accordance with some embodiments of the disclosure.

In addition, the inner spacer layers 136 are formed on the substrate 101 and the dummy gate electrode layer 118. Afterwards, the portion of the inner spacer layers 136 outside of the cavities 131 is removed.

The inner spacer layers 136 are configured to as a barrier between an S/D structure 138 (formed later) and a gate structure 160 (formed later). The inner spacer layers 136 can reduce the parasitic capacitance between the S/D structure 138 (formed later) and the gate structure 160 (formed later).

The inner spacer layers 136 are directly below the gate spacer layer 124. The inner spacer layers 136 are formed on the sidewall surfaces of the first semiconductor layers 104. The interface between the inner spacer layers 136 and the semiconductor layers 104 is vertical and is substantially aligned with the sidewall surface of the gate spacer layer 124. In some other embodiments, the interface between the inner spacer layers 136 and the semiconductor layers 104 is curved.

In some embodiments, the inner spacer layers 136 are made of silicon carbon nitride (SiCN) [symbol] carbonitride (SiOCN), or a combination thereof. In some embodiments, the inner spacer layers 136 are formed by a deposition process, such as CVD process, ALD process, another applicable process, or a combination thereof.

FIGS. 2A-2J show cross-sectional representations of various stages of forming a semiconductor device structure 100b and a semiconductor device structure 100c, in accordance with some embodiments of the disclosure. The semiconductor structure 100b or the semiconductor structure 100c of FIG. 2A is similar to, or the same as, the semiconductor structure 100a of FIG. 1H-2, the difference between the FIG. 2A and FIG. 1H is that, two first dummy gate structure 122a and two second dummy gate structures 122b are formed over a first fin structure 110a over the first region 10 of the substrate 102 and a second fin structure 110b over the second region 20 of the substrate 102 in FIG. 2A, and each of the first inner spacer layers 136a has a curved inner sidewall toward to the semiconductor layers 104. The first fin structure 110a includes a number of first semiconductor layers 104a and a number of second semiconductor layers 106a alternatively stacked in a vertical direction. The second fin structure 110b includes a number of first semiconductor layers 104b and a number of second semiconductor layers 106b alternatively stacked in a vertical direction.

As shown in FIG. 2A, the first dummy gate structure 122a is formed over the first region 10, and the first dummy gate structure 122a includes a first dummy gate dielectric layer 116a, a first dummy gate electrode layer 118a and a first hard mask layer 120a. The second dummy gate structure 122b is formed over the second region 20, and the second dummy gate structure 122b includes a second dummy gate dielectric layer 116b, a second dummy gate electrode layer 118b and a second hard mask layer 120b.

Next, as shown in FIG. 2B, a first bottom layer 138a is formed over the first region 10, and a second bottom layer 138b is formed over the second region 20, in accordance with some embodiments. The first bottom layer 138a and the second bottom layer 138b are filled into the bottom of the S/D trench 129. As a result, the top surface of the first bottom layer 138a is substantially level with the top surface of the second bottom layer 138b. The first bottom layer 138a and the second bottom layer 138b are used to define the locations of a first dielectric layer 142a (formed later) and a second dielectric layer 142b (formed later), and to further define the effective nanostructure number (e.g. nanosheet number) to achieve multi-nanostructures (e.g. multi-nanosheets) co-exist.

In some embodiments, the first bottom layer 138a and the second bottom layer 138b are simultaneously formed, and the top surface of the first bottom layer 138a and the top surface of the second bottom layer 138b are in the same level.

The first bottom layer 138a and the substrate 102 can be made of different materials. In addition, the second bottom layer 138b and the substrate 102 can be made of different materials. In some embodiments, the first bottom layer 138a and the second bottom layer 138b independently include un-doped Si, un-doped SiGe or a combination thereof. In some embodiments, the first bottom layer 138a is made of un-doped SiGe, and the Germanium (Ge) concentration is in a range from about 15% to about 25%. In some embodiments, the second bottom layer 138b is made of un-doped SiGe, and the Germanium (Ge) concentration is in a range from about 15% to about 25%. If the Germanium (Ge) concentration of un-doped SiGe is higher than 25%, the strain of the semiconductor structure 100b and the semiconductor structure 100c may be too high. If the Germanium (Ge) concentration of un-doped SiGe is lower than 15%, the etching selectivity of the first bottom layer 138a or the second bottom layer 138b in relating to the first gate spacer layer 124a or the second semiconductor layer 106 is not good enough during the etching process for removing the portion of the second bottom layer 138b in FIG. 2C.

In some embodiments, the first bottom layer 138a and the second bottom layer 138b independently are formed by an epitaxy or epitaxial (epi) process. The epi process may include a selective epitaxial growth (SEG) process, CVD deposition techniques (e.g., vapor-phase epitaxy (VPE) and/or ultra-high vacuum CVD (UHV-CVD)), molecular beam epitaxy, or other suitable epi processes.

Afterwards, as shown in FIG. 2C, a portion of the second bottom layer 138b is removed, in accordance with some embodiments. As a result, the top surface of the first bottom layer 138a is higher than the top surface of the second bottom layer 138b. In addition, the volume of the first bottom layer 138a is greater than the volume of the second bottom layer 138b. The top surface of the first bottom layer 138a is higher than the bottommost one of second semiconductor layers 106a over the first region 10, and the top surface of the second bottom layer 138b is lower than the bottommost one of second semiconductor layers 106b over the second region 20. In some embodiments, the portion of the second bottom layer 138b is removed by an etching process.

Afterwards, as shown in FIG. 2D, a dielectric material layer 141 is conformally formed on the first dummy gate structure 122a and the first bottom layer 138a over the first region 10, and on the second dummy gate structure 122b and the second bottom layer 138b over the second region 20, in accordance with some embodiments.

In some embodiments, the dielectric material layer 141 is made of SiN, SiON, SiOCN, SiOC, SiCN, SiOx, AlOx, HfOx or another applicable material. In some embodiments, the dielectric material layer 141 is formed by a deposition process, such as CVD process, ALD process, another applicable process, or a combination thereof. In some embodiments, the dielectric material layer 141 is formed by an ALD or an ALD-like process. In some embodiments, the ALD process is performed at a pressure in a range from about 1 Torr to about 8 Torr. In some embodiments, the ALD process is performed at a temperature in a range from about 350 Cesium degrees to about 600 Cesium degrees. In some embodiments, the ALD process is performed by using a gas including SiH₄,SiCl₂H₂,NH₃,Ar,N₂, or applicable gas.

Next, as shown in FIG. 2E, a treatment process is performed on the dielectric material layer 141, and an etching process is performed to remove a portion of the dielectric material layer 141, in accordance with some embodiments. As a result, a first dielectric layer 142a is formed over the first bottom layer 138a over the first region 10, and a second dielectric layer 142b is formed over the second bottom layer 138b over the second region 20.

The first dielectric layer 142a is higher than the second dielectric layer 142b. More specifically, the top surface of the first dielectric layer 142a is higher than the top surface of the second dielectric layer 142b. The top surface of the first dielectric layer 142a is higher than one of the bottom surface of the first inner spacer layers 136a and lower than one of the top surface of the first inner spacer layers 136a. In other words, the first dielectric layer 142a is in direct contact with a middle point of the first inner spacer layers 136a. The bottom surface of the first dielectric layer 142a is substantially level with one of the bottom surface of the first inner spacer layers 136a. The first dielectric layer 142a is higher than the bottommost of the second semiconductor layers 106a over the first region 10. The second dielectric layer 142b is lower than the bottommost of the second semiconductor layers 106b over the second region 20.

Some of the first inner spacer layers 136a are in direct contact with the first dielectric layer 142a, and some of the second inner spacer layers 136b are in direct contact with the second dielectric layer 142b. In addition, the top surface of the first dielectric layer 142a is lower than the top surface of one of the first inner spacer layers 136a.

In some embodiments, the property of bottom portions of the dielectric material 141 is modified by the treatment process, and therefore the bottom portions which are directly over the first bottom layer 138a and the second bottom layer 138b are not easily removed by the etching process after the treatment process. In other words, the bottom portion of the dielectric material 141 and the vertical portions of the dielectric material 141 have different etching selectivity after the treatment process, and therefore the bottom portions are not easily removed by the etching process. The etching rate of the bottom portions of the dielectric material 141 is lower than that of the vertical portions of the dielectric material 141. In some embodiments, the treatment process is performed by a plasma process using a gas including N₂, Ar, He, Ne, Kr or a combination thereof. The chemical bonds of the vertical portions of the dielectric material 141 are broken by the gas of the plasma process.

The height of one of the first inner spacer layers 136a is greater than the height of the first dielectric layer 142a in a vertical direction (along Z-axis). The height of one of the second inner spacer layers 136b is greater than the height of the second dielectric layer 142b. In some embodiments, the height of one of the first inner spacer layers 136a is in a range from about 7 nm to about 15 nm. In some embodiments, the height of one of the second inner spacer layers 136b is in a range from about 7 nm to about 15 nm. In some embodiments, the height of the first dielectric layer 142a is in a range from about 3 nm to about 8 nm. In some embodiments, the height of the second dielectric layer 142b is in a range from about 3 nm to about 8 nm.

FIG. 2E’ shows a cross-sectional representation of the semiconductor device structure 100b′ and the semiconductor device structure 100c, in accordance with some embodiments. FIG. 2E’ is a modified embodiment of FIG. 2E.

As shown in FIG. 2E’, the location of the first dielectric layer 142a over the first region 10 in FIG. 2E’ is lower than the location of the first dielectric layer 142a in FIG. 2E. The top surface of the first dielectric layer 142a is substantially level with one of the bottom surface of the first inner spacer layers 136a. The top surface of the first dielectric layer 142a is substantially level with the bottommost one of the second semiconductor layers 106a over the first region 10.

Next, as shown in FIG. 2F, a first source/drain (S/D) structure 146a is formed over the first bottom layer 142a over the first region 10, and a second S/D structure 146b is formed over the second bottom layer 142b, in accordance with some embodiments. The first S/D structure 146a is isolated from the first bottom layer 138a by the first dielectric layer 142a. The second S/D structure 146b is isolated from the second bottom layer 138b by the second dielectric layer 142b. The height of the first S/D structure 146a is less than the height of the second S/D structure 146b.

Some of the first inner spacer layers 136a are in direct contact with the first bottom layer 138a, the first dielectric layer 142a, and the first S/D structure 146a. Some of the second inner spacer layers 136b are in direct contact with the second bottom layer 138b, the second dielectric layer 142b, and the second S/D structure 146b.

FIG. 2F’ shows a cross-sectional representation of the semiconductor device structure 100b-1 and the semiconductor device structure 100c-1, in accordance with some embodiments. FIG. 2F’ is a modified embodiment of FIG. 2F. In some embodiments, the first S/D structure 146a and the second S/D structure 146b may independently include more than one layer. In some embodiments, the first S/D structure 146a include a first doped layer 145a and the second S/D structure 146b includes a first doped layer 145b. The concentration of the first doped layer 145a is lower than the concentration of the first S/D structure 146a. The concentration of the first doped layer 145b is lower than the concentration of the second S/D structure 146b. The first S/D structure 146a and the second S/D structure 146b may include silicon germanium (SiGe), indium arsenide (InAs), indium gallium arsenide (InGaAs), indium antimonide (InSb), gallium arsenide (GaAs), gallium antimonide (GaSb), indium aluminum phosphide (InAlP), indium phosphide (InP), or a combination thereof. The first S/D structure 146a and the second S/D structure 146b may dope with one or more dopants. In some embodiments, the first S/D structure 146a or the second S/D structure 146b is silicon (Si) doped with phosphorus (P), arsenic (As), antimony (Sb), or another applicable dopant. Alternatively, the first S/D structure 146a or the second S/D structure 146b is silicon germanium (SiGe) doped with boron (B) or another applicable dopant.

In some embodiments, the first S/D structure 146a or the second S/D structure 146b is formed by an epitaxy or epitaxial (epi) process. The epi process may include a selective epitaxial growth (SEG) process, CVD deposition techniques (e.g., vapor-phase epitaxy (VPE) and/or ultra-high vacuum CVD (UHV-CVD)), molecular beam epitaxy, or other suitable epi processes.

In some embodiments, when an N-type FET (NFET) device is desired, the first S/D structure 146a or the second S/D structure 146b includes an epitaxially growing silicon (epi Si). Alternatively, when a P-type FET (PFET) device is desired, the first S/D structure 138a or the second S/D structure 138b includes an epitaxially growing silicon germanium (SiGe).

FIG. 2F” shows a cross-sectional representation of the semiconductor device structure 100b-2 and the semiconductor device structure 100c-2, in accordance with some embodiments. FIG. 2F” is a modified embodiment of FIG. 2F. In some embodiments, the first S/D structure 146a and the the second S/D structure 146b are formed in the same process. In some embodiments, the topmost surface of the second S/D structure 146b is higher than the topmost surface of the first S/D structure 146a when the first S/D structure 146a and the second S/D structure 146b are formed in the same process. In some other embodiments, the first S/D structure 146a and the second S/D structure 146b are formed in separated processes. In some other embodiments, the topmost surface of the second S/D structure 146b is higher than the topmost surface of the first S/D structure 146a when the first S/D structure 146a and the second S/D structure 146b are formed in separated processes and the condition of the formation process for forming the first S/D structure 146a is different from that of for forming the second S/D structure 146b.

Afterwards, as shown in FIG. 2G, a contact etch stop layer (CESL) 150 is formed over the first S/D structure 138a and the second S/D structure 138b, and an inter-layer dielectric (ILD) layer 152 is formed over the CESL 150, in accordance with some embodiments.

Next, a portion of the ILD layer 152 is removed to expose the top surface of the first hard mask layer 120a and the second hard mask layer 120b. In some embodiments, the portion of the ILD layer 152 is removed by a planarizing process, a chemical mechanical polishing (CMP) process.

Next, as shown in FIG. 2H, the first hard mask layer 120a, the first dummy gate electrode layer 118a and the first dummy gate dielectric layer 116a are removed to form a first trench 155a, and the second hard mask layer 120b, the second dummy gate electrode layer 118b and the second dummy gate dielectric layer 116b are removed to form a second trench 155b, in accordance with some embodiments.

Afterwards, the first semiconductor layer 104a over the first region 10 and the first semiconductor layers 104b over the second region 20 are removed to form a number of first gaps 157a over the first region 10 and a number of second gaps 157b over the second region 20, in accordance with some embodiments. As a result, a number of stacked structures made of the second semiconductor layers 106a/106b are obtained. A number of nanostructures (e.g. the second semiconductor layers 106a/106b) are stacked in the vertical direction.

Afterwards, as shown in FIG. 2I, a first gate structure 165a is formed in the first trench 155a and the first gaps 157a over the first region 10, a second gate structure 165b is formed in the second trench 155b and the second gaps 157b over the second region 20, in accordance with some embodiments. As a result, the number of nanostructures (e.g. the second semiconductor layers 106a in the first region 10) are surrounded by the first gate structure 165a in the first region 10, and the number of nanostructures (e.g. the second semiconductor layers 106b in the second region 20) are surrounded by the second gate structure 165b in the second region 20. The portion of the second semiconductor layers 106a in the first region 10 covered by the first gate structure 165a can be referred to as a channel region. The portion of the second semiconductor layers 106b in the second region 20 covered by the second gate structure 165b can be referred to as a channel region.

The first gate structure 165a includes a first gate dielectric layer 162a and a first gate electrode layer 164a. The second gate structure 165b includes a second gate dielectric layer 162b and a second gate electrode layer 164b. The first gate dielectric layer 162a is conformally formed along the main surfaces of the second semiconductor layers 106a to surround the second semiconductor layers 106a over the first region 10. The second gate dielectric layer 162b is conformally formed along the main surfaces of the second semiconductor layers 106b to surround the second semiconductor layers 106b over the second region 20. The first inner spacer layers 136a are between the first gate structure 165a and the first S/D structure 146a. The second inner spacer layers 136b are between the second gate structure 165b and the second S/D structure 146b.

In some embodiments, the first gate dielectric layer 162a and the second gate dielectric layer 162b independently include a high-k dielectric layer. In some embodiments, the high-k gate dielectric layer is made of one or more layers of a dielectric material, such as HfO₂, HfSiO, HfSiON, HfTaO, HfTiO, HfZrO, zirconium oxide, aluminum oxide, titanium oxide, hafnium dioxide-alumina (HfO₂—Al2O₃) alloy, another suitable high-k dielectric material, or a combination thereof. In some embodiments, the high-k gate dielectric layer is formed using chemical vapor deposition (CVD), atomic layer deposition (ALD), another suitable method, or a combination thereof.

In some embodiments, the first gate electrode layer 164a and the second gate electrode layer 164b independently include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof.

In addition, the first gate electrode layer 164a and the second gate electrode layer 164b independently include one or more layers of n-work function layer or p-work function layer. In some embodiments, the n-work function layer includes tungsten (W), copper (Cu), titanium (Ti), silver (Ag), aluminum (Al), titanium nitride (TiN), tantalum nitride (TaN), tantalum carbide (TaC), titanium aluminum alloy (TiAl), titanium aluminum nitride (TiAlN), tantalum carbon nitride (TaCN), tantalum silicon nitride (TaSiN), manganese (Mn), zirconium (Zr) or a combination thereof. In some embodiments, the p-work function layer includes titanium (Ti), titanium nitride (TiN), tantalum nitride (TaN), tantalum carbide (TaC), molybdenum nitride, tungsten nitride (WN), ruthenium (Ru) or a combination thereof.

Afterwards, as shown in FIG. 2J, a portion of the CESL 150 and a portion of the ILD layer 152 are removed, in accordance with some embodiments. Next, a first metal silicide layer 166a is formed over the first S/D structure 146a, and a first contact structure 168a is formed over the first metal silicide layer 166a over the first region 10. A second metal silicide layer 166b is formed over the second S/D structure 146b, and a second contact structure 168b is formed over the second metal silicide layer 166b over the second region 20.

FIG. 2J′ shows a cross-sectional representation of the semiconductor device structure 100b-3 and the semiconductor device structure 100c-3, in accordance with some embodiments. FIG. 2J′ is a modified embodiment of FIG. 2J. The top surface of the first dielectric layer 142a is convex. The top surface of the second dielectric layer 142b is convex.

FIG. 2J″ shows a cross-sectional representation of the semiconductor device structure 100b-4 and the semiconductor device structure 100c-4, in accordance with some embodiments. FIG. 2J″ is a modified embodiment of FIG. 2J. The top surface of the first dielectric layer 142a is concave. The top surface of the second dielectric layer 142b is concave.

The fabrication method of the first metal silicide layer 166a and the second metal silicide layer 166b are described below. The metal layer (not shown) is formed first. Afterwards, the metal layer reacts with the silicon in the first S/D structure 146a and the second S/D structure 146b to form the first metal silicide layer 166a and the second metal silicide layer 166b during the annealing process. In some embodiments, the first metal silicide layer 166a and the second metal silicide layer 166b independently include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other applicable material. In some embodiments, the metal layer is made of titanium (Ti), and the first metal silicide layer 166a is made of titanium silicide (TiSix). In some other embodiments, the metal layer is made of tantalum (Ta), and the first metal silicide layer 166a is made of or tantalum silicide (TaSix).

The first contact structure 168a and the second contact structure 168b may be made of tungsten (W), tungsten alloy, aluminum (Al), aluminum alloy, copper (Cu) or copper alloy, cobalt (Co) or cobalt alloy. The first contact structure 168a and the second contact structure 168b may be formed by a deposition process, such as a chemical vapor deposition (CVD) process, physical vapor deposition (PVD) process, atomic layer deposition (ALD) process, plating process or another application process.

The first dielectric layer 142a is higher than the bottommost nanostructure (e.g. the second semiconductor layers 106a in the first region 10). In addition, the second dielectric layer 142b is lower than the bottommost nanostructure (e.g. the second semiconductor layers 106a in the first region 10). There is an interface between the first bottom layer 138a and the first dielectric layer 142a higher than the bottommost of the nanostructures (the second semiconductor 106a in the first region 10). There is an interface between the second bottom layer 138b and the second dielectric layer 142a lower than the bottommost nanostructure (the second semiconductor 106a in the second region 20). In some other embodiments, the first dielectric layer 142a is in direct contact with the bottommost of the nanostructures (second semiconductor layers 106).

The locations of the first dielectric layer 142a and the second dielectric layer 142b determinate the function of the nanostructure (e.g. the second semiconductor layers 106a in the first region 10) workable or not. The bottommost nanostructure (e.g. the second semiconductor layers 106a in the first region 10) in the first region 10 is below the first dielectric layer 142a, and it in direct contact with the first bottom layer 138a, rather than the first S/D structure 146a. Therefore, the bottommost one of nanostructures (e.g. the second semiconductor layers 106a in the first region 10) cannot perform the function of a channel of the semiconductor device structure 100b. The second dielectric layer 142b is lower than the bottommost one of nanostructures (e.g. the second semiconductor layers 106a in the second region 20), and therefore the bottommost one of nanostructures (e.g. the second semiconductor layers 106a in the second region 20 still can act as a channel of the semiconductor device structure 100c.

As mentioned above, the first bottom layer 138a and the second bottom layer 138b are used to define the effective (or active) nanostructure number (e.g. nanosheet number) and to achieve multi-nanostructures (e.g. nanosheets) co-exist. In the first region 10, the first dielectric layer 142a provides an isolation function, and therefore the first S/D structure 146a is isolated from the first bottom layer 138a by the first dielectric layer 142a. In the first region 10, there are three nanostructures (e.g. three second semiconductor layers 106a in the first region 10), but the effective (or active) nanostructure number becomes two due to the formation of the first bottom layer 138a and the first dielectric layer 142. In the second region 20, there are three nanostructures (e.g. three second semiconductor layers 106a in the first region 10), and the effective (or active) nanostructure number is also three.

More nanostructures (e.g. three second semiconductor layers 106a in the first region 10) can provide large effective width (W_{eff}) of the channel. The large effective width (W_{eff}) of channel can provide high speed of the semiconductor device structure. However, the larger effective width of the channel consumes more power. For high speed performance consideration, larger effective width (W_{eff}) is formed by having more nanostructures. For power efficiency, a smaller effective width (W_{eff}) is formed by having fewer nanostructures. In order to fulfill different needs in a region, the effective nanostructure number can be controlled by defining the locations of the first bottom layer 138a, the second bottom layer 138b, the first dielectric layer 142a and the second dielectric layer 142b. The effective nanostructure number of semiconductor device structure 100b in the first region 10 is fewer than the effective nanostructure number of the semiconductor device structure 100c in the second region 20. Therefore, the semiconductor device structure 100b in the first region 10 is formed for power efficiency and the semiconductor device structure 100c in the second region 20 is formed for high speed performance. The semiconductor device structure 100b and the semiconductor device structure 100c co-exist to achieve multi-nanostructures for speed performance and power efficiency.

It should be noted that the effective width (W_{eff}) of the channel may be controlled by adjusting the width of nanostructure along the X-direction or the Y-direction. If the semiconductor device structure with large effective width (W_{eff}) of the channel is designed along the X-direction or the Y-direction, it may occupy too much area. If the semiconductor device structure with small effective width (W_{eff}) of the channel is designed along the X-direction or the Y-direction, the process window for filling the gate structure or forming the S/D structure may be decreased. Therefore, in this disclosure, the effective width (W_{eff}) of the channel is controlled by defining the effective numbers of the nanostructures along the Z-direction, rather than in the X-direction or the Y-direction.

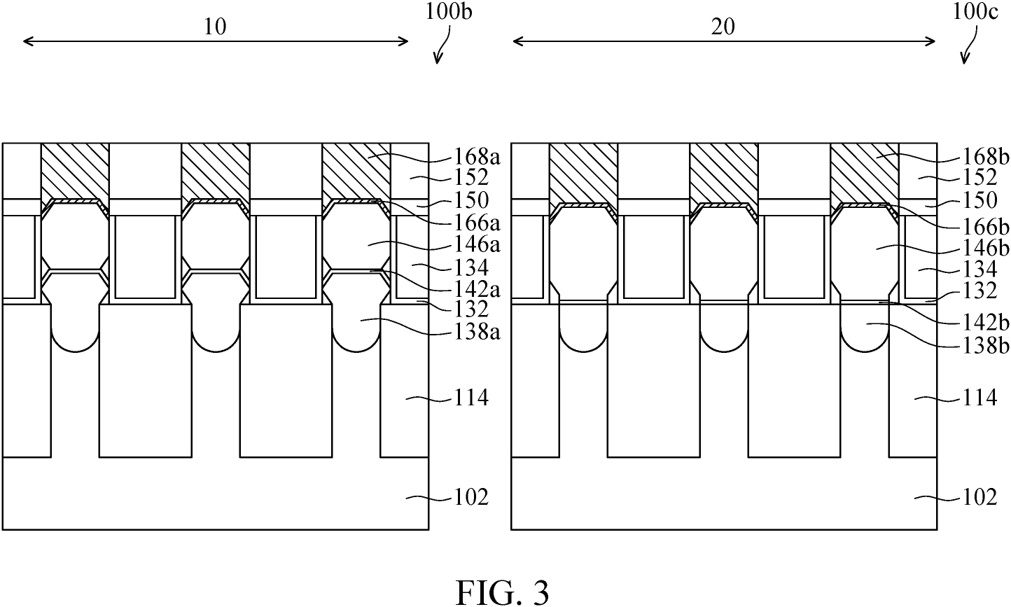

FIG. 3 shows a cross-sectional representation of the semiconductor device structure 100b and the semiconductor device structure 100c along Y-Y’ direction, in accordance with some embodiments of the disclosure.

As shown in FIG. 3, in the first region 10, the first bottom layer 138a is formed over the substrate 102, and the first dielectric layer 142a is formed over the first bottom layer 138a. The portion of the first bottom layer 138a is below the isolation structure 114. The first dielectric layer 142a is higher than the isolation structure 114. The first S/D structure 146a is formed over the first dielectric layer 142a.

There are dielectric fins between two adjacent first S/D structures 146a. Each of the dielectric fins includes a dielectric fill layer 134 over a dielectric liner 132. The dielectric liner 132 is in direct contact with the first dielectric layer 142a and the first S/D structure 146a, and the first metal silicide layer 166a.

In some embodiments, the dielectric liner 132 includes a high-k dielectric material, such as HfO₂, HfSiOx (such as HfSiO₄), HfSiON, HfLaO, HfTaO, HfTiO, HfZrO, HfAlOₓ, ZrO₂, ZrSiO₂, AlSiO, Al₂O₃, TiO₂, LaO, LaSiO, Ta₂O₃, Ta₂O₅, Y₂O₃, SrTiO₃, BaZrO, BaTiO₃ (BTO), (Ba,Sr)TiO₃ (BST), Si₃N₄, hafnium dioxide-alumina (HfO₂-Al₂O₃) alloy, other suitable high-k dielectric material, or combinations thereof. In some embodiments, the high-k dielectric material generally refers to dielectric materials having a high dielectric constant, for example, greater than 7. In some embodiments, the dielectric liner 132 is formed by a deposition process, such as CVD, PVD, ALD, HDPCVD, MOCVD, RPCVD, PECVD, LPCVD, ALCVD, APCVD, other suitable methods, or combinations thereof.

In some embodiments, the dielectric fill layer 134 includes a low-k dielectric material such as a dielectric material including Si, O, N, and C (for example, silicon oxide (SiO₂), silicon nitride, silicon oxynitride, silicon oxy carbide, silicon oxy carbon nitride). In an embodiment, the dielectric fill layer 134 includes tetraethylorthosilicate (TEOS) formed oxide, un-doped silicate glass, or doped silicon oxide such as borophosphosilicate glass (BPSG), fluoride-doped silica glass (FSG), phosphosilicate glass (PSG), boron doped silicon glass (BSG), other low-k dielectric materials, or combinations thereof. Some example low-k dielectric materials include Xerogel, Aerogel, amorphous fluorinated carbon, Parylene, polyimide, or combinations thereof. In some embodiments, low-k dielectric material generally refers to dielectric materials having a low dielectric constant, for example, lower than 7. In an embodiment, the dielectric fill layer 134 is formed by using a flowable CVD (FCVD) process that includes, for example, depositing a flowable material (such as a liquid compound) over the dielectric liner 132 and converting the flowable material to a solid material by a suitable technique, such as thermal annealing and/or ultraviolet radiation treating. In addition, the dielectric fill layer 134 may be formed by using other process.

In the second region 20, the second bottom layer 138b is formed over the substrate 102, and the second dielectric layer 142b is formed over the second bottom layer 138b. The portion of the second bottom layer 138b is below the isolation structure 114. The bottom surface of the second dielectric layer 142b is level with the top surface of the isolation structure 114. The dielectric liner 132 is in direct contact with the second S/D structure 146b and the second metal silicide layer 166b. The second S/D structure 146b is formed over the second dielectric layer 142b.

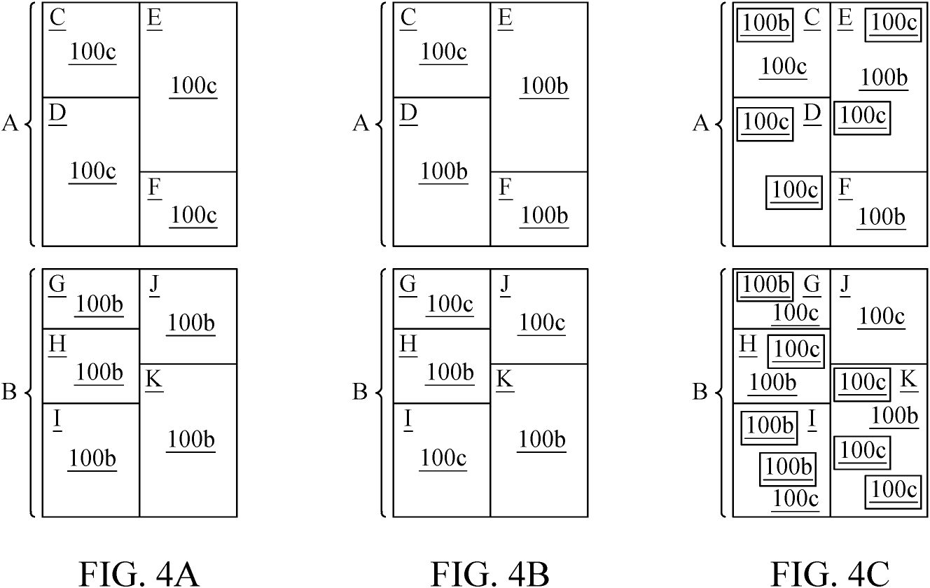

FIGS. 4A-4C show top-views of the layout of the first region 10 and the second region 20, in accordance with some embodiments of the disclosure. The semiconductor device structure 100b is formed in the first region 10, and the semiconductor device structure 100c is formed in the second region 20.

As shown in FIG. 4A, there are two blocks including block A and block B when seen from a top-view. In the block A, there are four cells including cell C, cell D, cell E and cell F. In the block B, there are five cells including cell G, cell H, cell I, cell J and cell K. A number of the semiconductor device structures 100c with three effective (or active) nanostructures are formed in block A, and a number of the semiconductor device structures 100b with two effective (or active) nanostructures are formed in the block B. Although four cells are formed in the block A and five cells are formed in the block B, the number of the cells can be adjusted according to the actual application.

As shown in FIG. 4B, in the block A, the semiconductor device structures 100c with three effective (or active) nanostructures are formed in the cell C, and the semiconductor device structure 100b with two effective (or active) nanostructures are in the cell D, cell E and cell F. In the block B, the semiconductor device structures 100c with three effective (or active) nanostructures are formed in the cell G, cell I and cell J, and the semiconductor device structure 100b with two effective (or active) nanostructures are in the cell H and cell K.

As shown in FIG. 4C, there are two different types of nanostructures in each cell. For example, the semiconductor device structure 100b with two effective (or active) nanostructures and the semiconductor device structures 100c with three effective (or active) nanostructures co-exist in a single cell C. In the block B, there are three semiconductor device structures 100c with three effective (or active) nanostructures and one the semiconductor device structure 100b with two effective (or active) nanostructures in the cell K. The layout of the cell and the number of the cell can be adjusted according to the actual application.

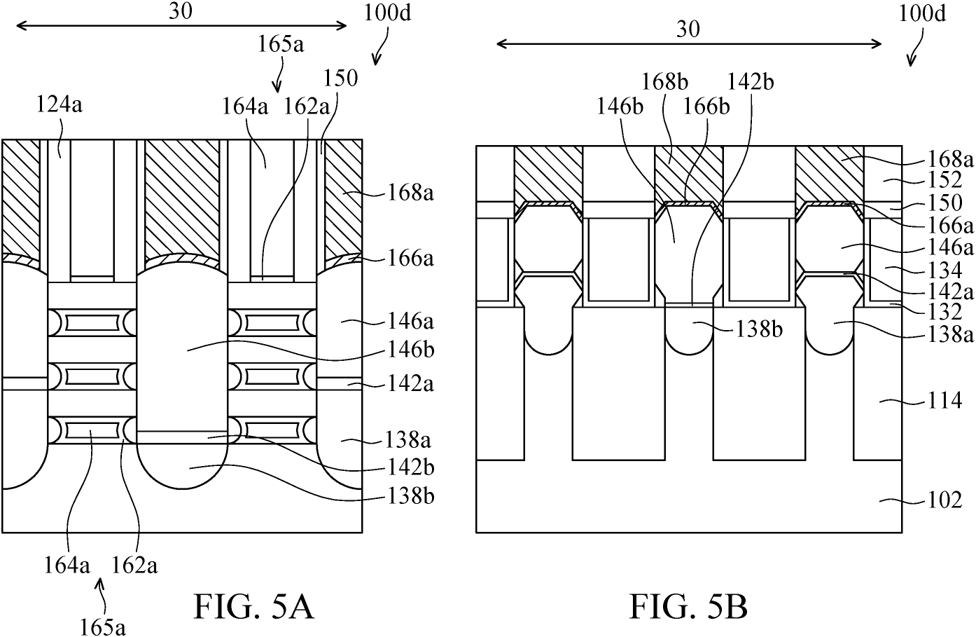

FIG. 5A shows a cross-sectional representation of the semiconductor device structure 100d along the Y-Y′ direction, in accordance with some embodiments. The semiconductor structure 100d of FIG. 5A is similar to, or the same as, the semiconductor structure 100b or the semiconductor structure 100c of FIG. 2J, the difference between the FIG. 2J and FIG. 1H is that, the first dielectric layer 142a and the second dielectric layer 142b are formed in a region 30 in FIG. 5A. The second dielectric layer 142b is formed between the second S/D structure 146b and the second bottom layer 138b in FIG. 5A to provide an isolation effect to prevent leakage. In some other embodiments, the second dielectric layer 142b is optional.

As shown in FIG. 5A, the substrate 102 further includes a third region 30, and there is three S/D structures in the third region 30. The second S/D structure 146b is in the middle, and two of the first S/D structures 146a are on opposite sides of the second S/D structure 146b. The second dielectric layer 142b is in the middle, and two of the first dielectric layers 142a are on opposite sides of the second dielectric layer 142b. The first dielectric layer 142a is higher than the second dielectric layer 142b. The top surface of the first bottom layer 138a is higher than the top surface of the second bottom layer 138b. The volume of the first bottom layer 138a is greater than the volume of the second bottom layer 138b. The first S/D structure 146a is smaller in size than the second S/D structure 146b. The height of the first S/D structure 146a is lower than the height of the second S/D structure 146b. In this embodiments, the semiconductor device structure 100d having S/D structure contacting with different number of the nanostructures is designed according to actual application and to increase diversity.

FIG. 5B shows a cross-sectional representation of the semiconductor device structure 100d along the X-X′ direction, in accordance with some embodiments. The semiconductor structure 100d of FIG. 5B is similar to, or the same as, the semiconductor structure 100b or the semiconductor structure 100c of FIG. 3, the difference between the FIG. 5B and FIG. 3 is that, the first dielectric layer 142a and the second dielectric layer 142b are formed in the region 30 in FIG. 5B.

As shown in FIG. 5B, the second dielectric layer 142b in the middle is lower than the first dielectric layer 142a at two sides of the second dielectric layer 142b. The bottom surface of the second S/D structure 146b is lower than the bottom surface of the first S/D structure 146a.

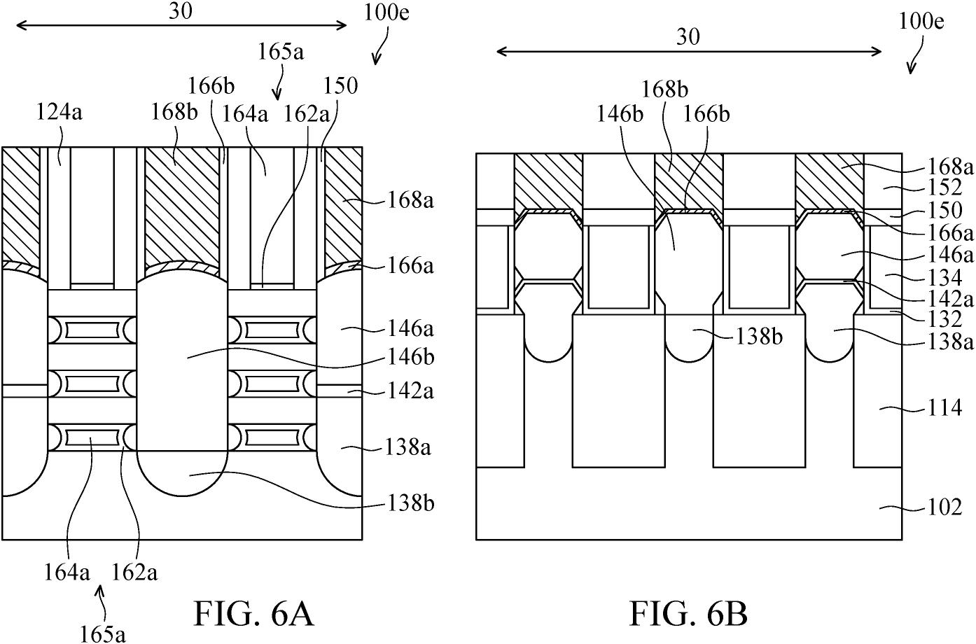

FIG. 6A shows a cross-sectional representation of the semiconductor device structure 100e along the Y-Y’ direction, in accordance with some embodiments. The semiconductor structure 100e of FIG. 6A is similar to, or the same as, the semiconductor structure 100d of FIG. 5A, the difference between the FIG. 6A and FIG. 5A is that, there is no dielectric layer between the second S/D structure 146b and the second bottom layer 138b in FIG. 6A.

As shown in FIG. 6A, the second S/D structure 146b is in direct contact with the second bottom layer 138b, there is no dielectric layer between the second S/D structure 146b and the second bottom layer 138b. The advantage of this embodiment is that the epitaxial quality of the second S/D structure 146b on the second bottom layer 138b is better than that of the second S/D structure 146b on a dielectric layer.

FIG. 6B shows a cross-sectional representation of the semiconductor device structure 100e along the X-X′ direction, in accordance with some embodiments. The semiconductor structure 100e of FIG. 6B is similar to, or the same as, the semiconductor structure 100d of FIG. 5B, the difference between the FIG. 6B and FIG. 5B is that, there is no dielectric layer between the second S/D structure 146b and the second bottom layer 138b in FIG. 6B.

As shown in FIG. 6B, the second S/D structure 146b is in direct contact with the second bottom layer 138b. In addition, the top surface of the second bottom layer 138b is substantially level with the top surface of the isolation structure 114.

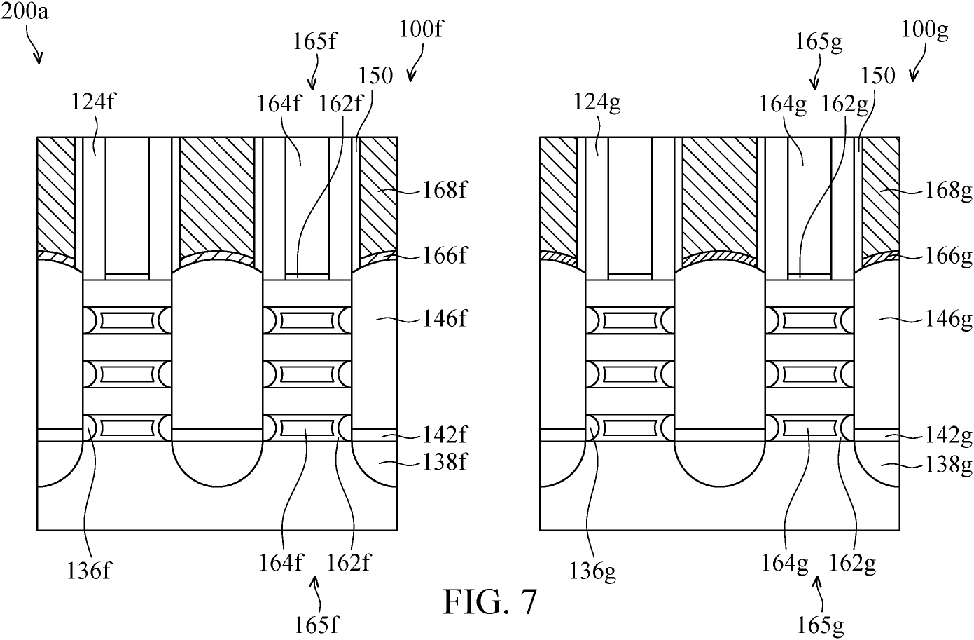

FIG. 7 shows a cross-sectional representation of the semiconductor device structure 200a along the Y-Y′ direction in a cell, in accordance with some embodiments. The cell may be cell C, cell D, cell E, cell F, cell G, cell H, cell I, cell J or cell K in FIGS. 4A-4C. The semiconductor device structure 200a includes a semiconductor device structure 100f and the semiconductor device structure 100g. The semiconductor device structure 100f and the semiconductor device structure 100g are similar to, or the same as, the semiconductor structure 100c of FIG. 2J.

In some embodiments, the semiconductor device structure 100f is a p-type FET field effect transistors (PFETs), and the semiconductor device structure 100g is an n-type field effect transistors (NFETs). The semiconductor device structure 100f has three effective (or active) nanostructures (e.g. second semiconductor layers 108) and the semiconductor device structure 100g also has three effective (or active)nanostructures (e.g. second semiconductor layers 108). The effective (or active) nanostructures are controlled by defining the location of the third dielectric layer 142f and the fourth dielectric layer 142g. The semiconductor device structure 200a is formed in the cell for speed performance consideration.

The semiconductor device structure 100f is includes a third bottom layer 138f, a third dielectric layer 142f and a third S/D structure 146f are sequentially formed over the substrate 102. The semiconductor device structure 100g is includes a fourth bottom layer 138g, a fourth dielectric layer 142g and a fourth S/D structure 146g are sequentially formed over the substrate 102. It should be noted that the material of the third S/D structure 146f is different from the material of the fourth S/D structure 146g.

In some embodiments, for p-type transistors, the third S/D structure 146f include silicon germanium or germanium and can be doped with boron, other p-type dopant, or combinations thereof (for example, forming Si:Ge:B epitaxial S/D structures). In some embodiments, for n-type transistors, the fourth S/D structure 146g include silicon and can be doped with carbon, phosphorous, arsenic, other n-type dopant, or combinations thereof (for example, forming Si:C epitaxial S/D structure, Si:P epitaxial S/D structures, or Si:C:P epitaxial S/D structures).

In some embodiments, when the third S/D structure 146f is made of Si:Ge:B epitaxial S/D structures, the diffusion of the boron (B) from the third S/D structure 146f into the third bottom layer 138f may be reduced due to the formation of the third dielectric layer 142f.

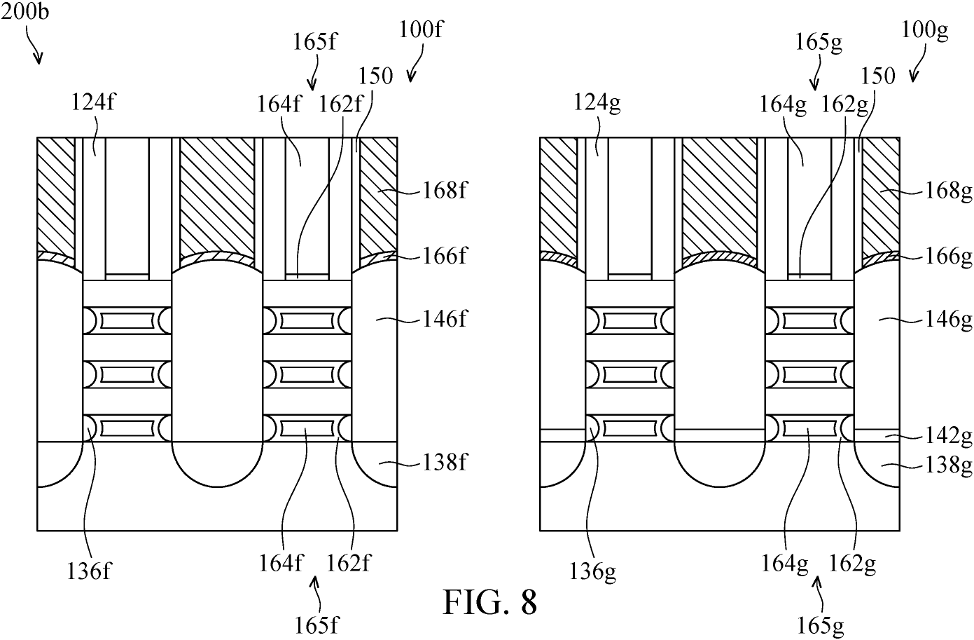

FIG. 8 shows a cross-sectional representation of the semiconductor device structure 200b along the Y-Y′ direction in a cell, in accordance with some embodiments. The semiconductor device structure 200b is similar to, or the same as, the semiconductor structure 200a of FIG. 7, the difference between the FIG. 8 and FIG. 7 is that, no dielectric layer is between third bottom layer 138f and the third S/D structure 146f in the semiconductor device structure 100f.

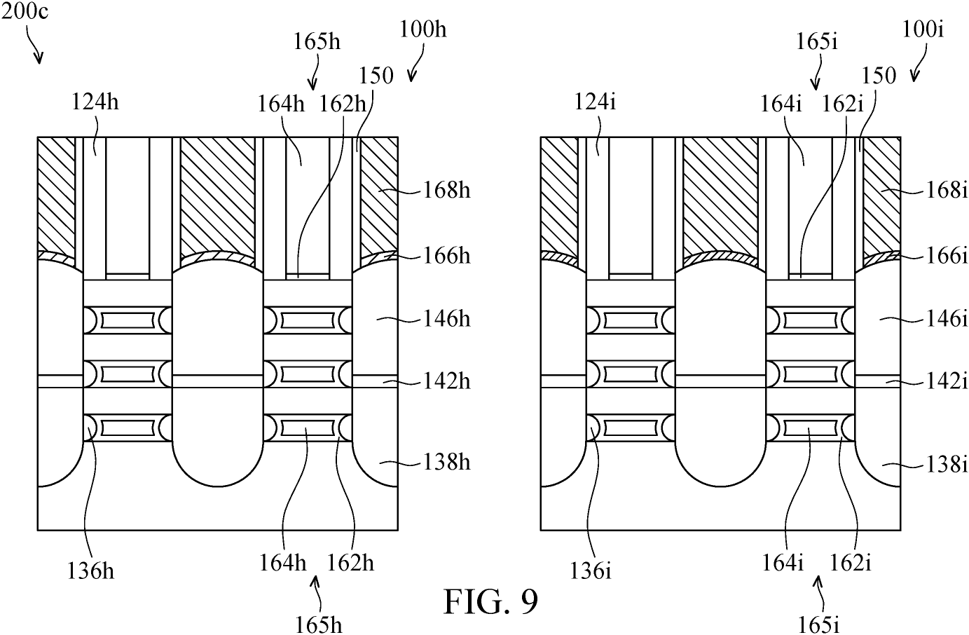

FIG. 9 shows a cross-sectional representation of the semiconductor device structure 200c along the Y-Y′ direction in a cell, in accordance with some embodiments. The cell may be cell C, cell D, cell E, cell F, cell G, cell H, cell I, cell J or cell K in FIGS. 4A-4C. The semiconductor device structure 200c includes a semiconductor device structure 100h and the semiconductor device structure 100i. The semiconductor device structure 100h and the semiconductor device structure 100i are similar to, or the same as, the semiconductor structure 100b of FIG. 2J.

In some embodiments, the semiconductor device structure 100h is a p-type FET field effect transistors (PFETs), and the semiconductor device structure 100i is an n-type field effect transistors (NFETs). The semiconductor device structure 100h has two effective (or active) nanostructures (e.g. second semiconductor layers 108) and the semiconductor device structure 100i also has two effective (or active) nanostructures (e.g. second semiconductor layers 108). The effective (or active) nanostructures are controlled by defining the location of the fifth dielectric layer 142h and the sixth dielectric layer 142i. The semiconductor device structure 200c is formed in the cell for power efficiency consideration.

The semiconductor device structure 100h is includes a fifth bottom layer 138h, a fifth dielectric layer 142h and a fifth S/D structure 146h are sequentially formed over the substrate 102. The semiconductor device structure 100i is includes a sixth bottom layer 138i, a sixth dielectric layer 142i and a sixth S/D structure 146i are sequentially formed over the substrate 102. It should be noted that the material of the fifth S/D structure 146h is different from the material of the sixth S/D structure 146i. In some embodiments, for p-type transistors, the fifth S/D structure 146h include silicon germanium or germanium and can be doped with boron, other p-type dopant, or combinations thereof (for example, forming Si:Ge:B epitaxial S/D structures). In some embodiments, for n-type transistors, the sixth S/D structure 146i include silicon and can be doped with carbon, phosphorous, arsenic, other n-type dopant, or combinations thereof (for example, forming Si:C epitaxial S/D structure, Si:P epitaxial S/D structures, or Si:C:P epitaxial S/D structures).

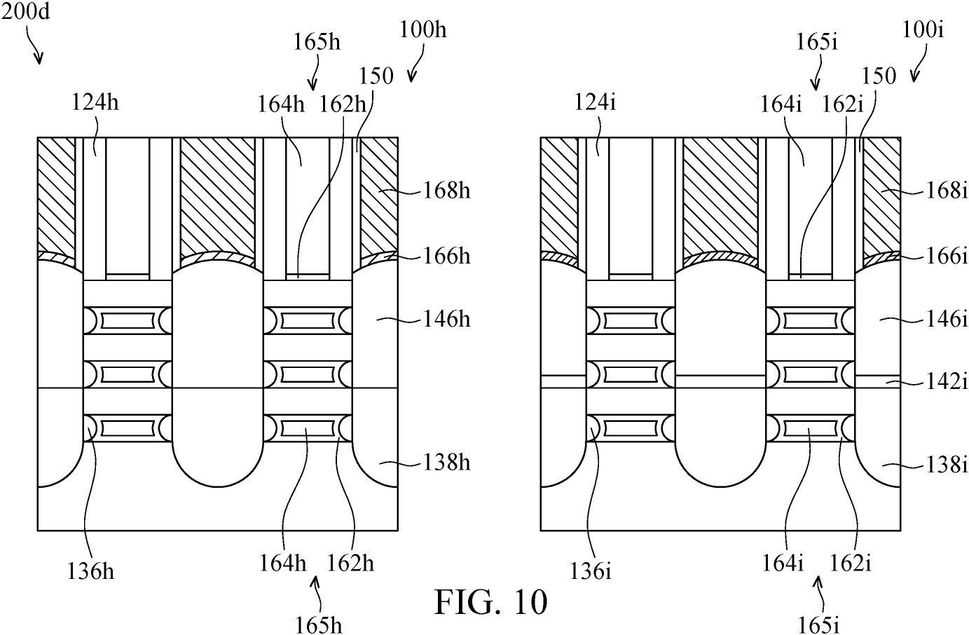

FIG. 10 shows a cross-sectional representation of the semiconductor device structure 200d along the Y-Y’ direction in a cell, in accordance with some embodiments. The semiconductor device structure 200d is similar to, or the same as, the semiconductor structure 200c of FIG. 9, the difference between the FIG. 10 and FIG. 9 is that, no dielectric layer is between fifth bottom layer 138h and the fifth S/D structure 146h in the semiconductor device structure 100h.

It should be note that the first bottom layer 138a, the first dielectric layer 142a, the second bottom layer 138b and the second dielectric layer 142b are used to define the effective (or active) nanostructure number (e.g. nanosheet number). The connection of nanostructures below the first dielectric layer 142a is blocked, and therefore the effective (or active) nanostructure number is determined by the locations of the first bottom layer 138a, the first dielectric layer 142a, the second bottom layer 138b and the second dielectric layer 142b. The different effective (or active) nanostructure numbers can be designed in a cell to fulfill different needs (for speed performance consideration or power efficiency consideration).

Embodiments for forming a semiconductor device structure and method for formation the same are provided. The first fin structure formed over a substrate, and the first fin structure includes a number of nanostructures. A first bottom layer adjacent to the first fin structure, and a first dielectric layer formed over the first bottom layer. A first S/D structure formed over the first dielectric layer. The first dielectric layer is higher than the bottommost nanostructure. The effective (or active) nanostructures are controlled by defining the location of the first dielectric layer. The multi-nanostructures co-exist by controlling the locations of the first bottom layer and the first dielectric layer. More effective (or active) nanostructures can improve the speed of the semiconductor device structure, fewer effective (or active) nanostructures can increase the power efficiency. Therefore, the semiconductor device structure includes more effective (or active) nanostructures in a region for speed performance consideration and fewer effective (or active) nanostructures in another region for power efficiency consideration. Therefore, the performance of semiconductor device structure is improved.

In some embodiments, a semiconductor device structure is provided. The semiconductor device structure includes a plurality of first nanostructures stacked over a substrate in a vertical direction. The semiconductor device structure also includes a first bottom layer formed adjacent to the first nanostructures, and a first dielectric layer formed over the first bottom layer. The semiconductor device structure further includes a first source/drain (S/D) structure formed over the first dielectric layer, and the first S/D structure is isolated from the first bottom layer by the first dielectric layer.

In some embodiments, a semiconductor device structure is provided. The semiconductor device structure includes a substrate, and the substrate includes a first region and a second region. The semiconductor device structure also includes a plurality of first nanostructures stacked over the first region in a vertical direction. The semiconductor device structure also includes a first bottom layer adjacent to the first nanostructures, and a first dielectric layer formed over the first bottom layer. The semiconductor device structure includes a first source/drain (S/D) structure formed over the first dielectric layer, and a plurality of second nanostructures stacked over the second region in a vertical direction. The semiconductor device structure also includes a second bottom layer formed adjacent to the second nanostructures, and a second dielectric layer formed over the second bottom layer. The first dielectric layer is higher than a second dielectric layer. The semiconductor device structure includes a second source/drain (S/D) structure formed over the second dielectric layer.

In some embodiments, a method for forming a semiconductor device structure is provided. The method includes forming a first fin structure and a second fin structure over a substrate, and the first fin structure includes a plurality of first nanostructures stacked in a vertical direction, and the second fin structure includes a plurality of second nanostructures stacked in a vertical direction. The method also includes forming a dummy gate structure over the first fin structure and the second fin structure, and removing a portion of the first fin structure and a second fin structure to form a first recess and a second recess. The method also includes forming a first bottom layer in the first recess and a second bottom layer in the second recess. The method includes removing a portion of the second bottom layer, and a top surface of the first bottom layer is higher than a top surface of the second bottom layer. The method further includes forming a first dielectric layer over the first bottom layer and a second dielectric layer over the second bottom layer. The method includes forming a first source/drain (S/D) structure over the first dielectric layer and a second S/D structure over the second dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device structure, comprising:
a plurality of first nanostructures stacked over a substrate in a vertical direction;
a first bottom layer formed adjacent to the first nanostructures ;
a first dielectric layer formed over the first bottom layer; and
a first source/drain (S/D) structure formed over the first dielectric layer, wherein the first S/D structure is isolated from the first bottom layer by the first dielectric layer.

2. The semiconductor device structure as claimed in claim 1, further comprising:
a gate structure surrounding the first nanostructures; and
an inner spacer between the gate structure and the S/D structure, wherein the inner spacer is in direct contact with the first dielectric layer.

3. The semiconductor device structure as claimed in claim 2, wherein a top surface of the first dielectric layer is lower than a top surface of the inner spacer.

4. The semiconductor device structure as claimed in claim 2, wherein a height of the inner spacer is greater than a height of the first dielectric layer.

5. The semiconductor device structure as claimed in claim 1, wherein the dielectric layer is higher than a bottommost nanostructure of the first nanostructures.

6. The semiconductor device structure as claimed in claim 1, wherein the first bottom layer comprises un-doped Si, un-doped SiGe or a combination thereof.

7. The semiconductor device structure as claimed in claim 1, further comprising:
a second bottom layer formed adjacent to the first nanostructures; and
a second dielectric layer formed over the second bottom layer, wherein the first dielectric layer is higher than the second dielectric layer.

8. The semiconductor device structure as claimed in claim 1, further comprising:
a plurality of second nanostructures stacked over a substrate in a vertical direction;
a second bottom layer adjacent to the second nanostructures; and
a second S/D structure formed over the second bottom layer, wherein the second S/D structure is in direct contact with the second bottom layer.

9. The semiconductor device structure as claimed in claim 1, wherein the first bottom layer and the substrate are made of different materials..

10. The semiconductor device structure as claimed in claim 1, wherein a top surface of the first bottom layer is higher than a bottommost nanostructure of the first nanostructures.

11. A semiconductor device structure, comprising:
a substrate, wherein the substrate comprises a first region and a second region ;
a plurality of first nanostructures stacked over the first region in a vertical direction;
a first bottom layer adjacent to the first nanostructures;
a first dielectric layer formed over the first bottom layer;
a first source/drain (S/D) structure formed over the first dielectric layer;
a plurality of second nanostructures stacked over the second region in a vertical direction;
a second bottom layer formed adjacent to the second nanostructures ;
a second dielectric layer formed over the second bottom layer, wherein the first dielectric layer is higher than a second dielectric layer; and
a second source/drain (S/D) structure formed over the second dielectric layer.

12. The semiconductor device structure as claimed in claim 11, wherein a first height of the first S/D structure is lower than a second height of the second S/D structure.

13. The semiconductor device structure as claimed in claim 11, further comprising:
a first gate structure surrounding the first nanostructures; and
an inner spacer between the first gate structure and the first S/D structure, wherein the inner spacer is in direct contact with the first dielectric layer.

14. The semiconductor device structure as claimed in claim 13, wherein a height of the inner spacer is greater than a height of the first dielectric layer.

15. The semiconductor device structure as claimed in claim 11, wherein an interface between the first bottom layer and the first dielectric layer is higher than a bottommost nanostructure of the first nanostructures.

16. The semiconductor device structure as claimed in claim 11, wherein the first dielectric layer is in direct contact with a bottommost nanostructure of the first nanostructures.

17. A method for forming a semiconductor device structure, comprising:
forming a first fin structure and a second fin structure over a substrate, wherein the first fin structure comprises a plurality of first nanostructures stacked in a vertical direction, and the second fin structure comprises a plurality of second nanostructures stacked in a vertical direction;
forming a dummy gate structure over the first fin structure and the second fin structure;
removing a portion of the first fin structure and a second fin structure to form a first recess and a second recess;
forming a first bottom layer in the first recess and a second bottom layer in the second recess;
removing a portion of the second bottom layer, wherein a top surface of the first bottom layer is higher than a top surface of the second bottom layer;
forming a first dielectric layer over the first bottom layer and a second dielectric layer over the second bottom layer; and
forming a first source/drain (S/D) structure over the first dielectric layer and a second S/D structure over the second dielectric layer.

18. The method for forming the semiconductor device structure as claimed in claim 17, wherein the first nanostructures comprise a plurality of first semiconductor layers and a plurality of second semiconductor layers alternately stacked, and the method comprises:
removing a portion of the first semiconductor layers to form a recess;
forming an inner spacer in the recess; and
forming the first bottom layer adjacent to the inner spacer.

19. The method for forming the semiconductor device structure as claimed in claim 17, further comprising:
removing the dummy gate structure;
removing a first portion of the first nanostructures; and
forming a gate structure surrounding a second portion of the first nanostructures.

20. The method for forming the semiconductor device structure as claimed in claim 17, wherein forming the first dielectric layer over the first bottom layer further comprises:
forming a first dielectric material over the dummy gate structure and the first bottom layer; and
performing a treatment process on the first dielectric material; and
removing a portion of the first dielectric material to form the first dielectric layer.
